(19) United States
(12) Patent Application Publication
(10) Pub. No.: US 2024/0298477 A1
(43) Pub. Date: Sep. 5, 2024

(54) DISPLAY PANEL AND MANUFACTURING METHOD OF THE SAME

(71) Applicant: Samsung Display Co., LTD., Yongin-si (KR)

(72) Inventors: YOUNGSEOK BAEK, Yongin-si (KR); SANGJIN PARK, Yongin-si (KR); DONGHYUN YANG, Yongin-si (KR); INKYUNG YOO, Yongin-si (KR)

(21) Appl. No.: 18/517,753

(22) Filed: Nov. 22, 2023

(30) Foreign Application Priority Data
Mar. 3, 2023 (KR) 10-2023-0028721

(51) Int. Cl. H10K 59/122; H10K 59/12

(52) U.S. Cl. CPC H10K 59/122; H10K 59/1201

(57) ABSTRACT

Provided is a display panel including a base layer, an insulating layer having a groove defined thereon and disposed on the base layer, an anode disposed in the groove, a pixel defining layer disposed on the insulating layer and having a first light-emitting opening defined therein and exposing at least a portion of the anode, a partition wall having a partition wall opening defined therein and corresponding to the light-emitting opening, including a tip portion, and disposed on the pixel defining layer, a cathode at least partially disposed in the partition wall opening and in contact with an inner side surface of the partition wall defining the partition wall opening, and a light-emitting pattern disposed between the anode and the cathode, wherein the anode includes a first portion and a second portion protruding from the first portion toward the pixel defining layer and covered by the pixel defining layer.

This application claims priority to Korean Patent Application No. 10-2023-0028721, filed on Mar. 3, 2023, and all the benefits accruing therefrom under § 35 U.S.C. 119, the content of which in its entirety is herein incorporated by reference.

### BACKGROUND

### (1) Field

The present disclosure relates to a display panel, and more particularly, to a display panel with improved display efficiency and a method for manufacturing the same.

### (2) Description of the Related Art

A display device is activated in response to an electrical signal. The display device may include a display panel for displaying an image, wherein the display panel, an organic light-emitting display panel has low power consumption, high luminance, and high response speed.

The organic light-emitting display panel among display panels includes an anode, a cathode, and a light-emitting pattern wherein the light-emitting pattern is separated for each light-emitting region and the cathode provides a common voltage to each light-emitting region.

### SUMMARY

The present disclosure provides an embodiment of a display panel including a light-emitting element formed without using a metal mask and a method of manufacturing the display panel.

The present disclosure also provides an embodiment of a display panel with improved process reliability and a method of manufacturing the display panel.

The present disclosure also provides an embodiment of a display panel with improved display efficiency and an improved degree of design freedom and a method of manufacturing the display panel.

An embodiment of the invention provides a display panel including a base layer, an insulating layer having a groove defined thereon and disposed on the base layer, an anode disposed in the groove, a pixel defining layer disposed on the insulating layer and having a light-emitting opening defined therein and exposing at least a portion of the anode, a partition wall having a partition wall opening defined therein and corresponding to the light-emitting opening, including a tip portion, and disposed on the pixel defining layer, a cathode at least partially disposed in the partition wall opening and in contact with an inner side surface of the partition wall defining the partition wall opening and a light-emitting pattern disposed between the anode and the cathode, wherein the anode includes a first portion and a second portion protruding from the first portion toward the pixel defining layer and covered by the pixel defining layer.

In an embodiment, an upper surface of the second portion of the anode covered by the pixel defining layer may be substantially coplanar with an upper surface of the insulating layer.

In an embodiment, the display panel may further include a sacrificial pattern disposed on the first portion in the groove, covered by the pixel defining layer, and having a sacrificial opening defined therein and corresponding to the light-emitting opening, wherein the sacrificial pattern may be surrounded by the second portion.

In an embodiment, an upper surface of the sacrificial pattern and an upper surface of the insulating layer may be substantially coplanar with each other.

In an embodiment, the insulating layer may be composed of a single layer.

In an embodiment, the insulating layer may include a lower film and an upper film having an opening defined therein and disposed on the lower film, wherein the groove may be defined by the opening and an upper surface of the lower film exposed from the opening.

In an embodiment, the pixel defining layer may be generally flat.

In an embodiment, the partition wall may include a first layer including a first inner side surface defining a first region of the partition wall opening and a second layer disposed on the first layer and including a second inner side surface defining a second region of the partition wall opening, wherein the first inner side surface may be disposed more inwardly than the second inner side surface, the tip portion may correspond to the second layer protruding from the first layer and an upper surface of the second layer may be generally flat.

In an embodiment, the pixel defining layer may contain an inorganic insulating material.

In an embodiment of the invention, the display panel may further include a first dummy pattern disposed on the partition wall, containing the same material as the light-emitting pattern, and spaced apart from the light-emitting pattern, a second dummy pattern disposed on the first dummy pattern, containing the same material as the cathode, and spaced apart from the cathode and a lower encapsulation inorganic pattern disposed to correspond to the light-emitting opening and disposed on the cathode and the second dummy pattern.

In an embodiment of the invention, a method for manufacturing a display panel includes forming an anode in a groove defined in an insulating layer, forming a partition wall disposed on the insulating layer and having a partition wall opening defined therein and overlapping the anode, forming a pixel defining layer disposed between the insulating layer and the partition wall and having a light-emitting opening defined therein and corresponding to the partition wall opening, forming a light-emitting pattern at least partially disposed in the groove and the light-emitting opening and forming a cathode at least partially disposed in the partition wall opening and coming in contact with an inner side surface of the partition wall defining the partition wall opening, wherein an upper surface of the anode covered by the pixel defining layer is substantially coplanar with an upper surface of the insulating layer.

In an embodiment of the invention, the method for manufacturing the display panel may further include, before the forming of the anode, depositing a first preliminary insulating layer on a base layer and forming an initial groove in the first preliminary insulating layer so that a second preliminary insulating layer is formed from the first preliminary insulating layer, wherein the forming of the initial groove in the first preliminary insulating layer may include providing light to the first preliminary insulating layer by using a mask having a mask opening defined therein and removing a portion of the first preliminary insulating layer exposed to the light.

In an embodiment, in the providing of the light to the first preliminary insulating layer, the light having a first amount of light per unit area may be provided to a portion of the first preliminary insulating layer overlapping the mask opening, and the light having a second amount of light per unit area may be provided to a portion of the first preliminary insulating layer overlapping the mask, wherein the first amount of light may be greater than the second amount of light.

In an embodiment, the forming of the anode may include forming a conductive layer on the second preliminary insulating layer, patterning the conductive layer to form a preliminary anode, which overlaps the initial groove, from the conductive layer and removing a portion of the preliminary anode and a portion of the second preliminary insulating layer to form the anode and the insulating layer from the preliminary anode and the second preliminary insulating layer, respectively, wherein, in the removing of the portion of the preliminary anode and the portion of the second preliminary insulating layer, the groove having a smaller depth than the initial groove may be formed from the initial groove.

In an embodiment, the forming of the anode may further include, after the forming of the conductive layer and before the patterning of the conductive layer, forming a sacrificial layer on the conductive layer and patterning the sacrificial layer so that a preliminary sacrificial pattern overlapping the initial groove is formed from the sacrificial layer, and in the removing of the portion of the preliminary anode and the portion of the second preliminary insulating layer, a portion of the preliminary sacrificial pattern may be removed together so that a sacrificial pattern may be formed from the preliminary sacrificial pattern, wherein an upper surface of the sacrificial pattern may be substantially coplanar with the upper surface of the insulating layer.

In an embodiment, the anode may include a first portion and a second portion extending in a direction away from the base layer and from the first portion and surrounding the sacrificial pattern, and the upper surface of the anode, which is substantially coplanar with the upper surface of the insulating layer, may be included in the second portion.

In an embodiment, the patterning of the conductive layer may be performed by a wet etching method.

In an embodiment, the removing of the portion of the preliminary anode and the portion of the second preliminary insulating layer may be performed by a chemical mechanical polishing (CMP) method.

In an embodiment, the depositing of the first preliminary insulating layer may include depositing a lower film on the base layer and depositing a first preliminary upper film on the lower film, in the forming of the initial groove on the first preliminary insulating layer, a second preliminary upper film having an initial opening defined therein may be formed from the first preliminary upper film, wherein the initial groove may be formed by the initial opening and an upper surface of the lower film exposed from the initial opening and in the removing of the portion of the preliminary anode and the portion of the second preliminary insulating layer, a portion of the second preliminary upper film may be removed to form an upper film thinner than the second preliminary upper film from the second preliminary upper film, wherein an opening formed from the initial opening may be defined in the upper film, and wherein the groove may be formed by the opening and the upper surface of the lower film exposed from the opening.

In an embodiment, in the providing of the light to the first preliminary insulating layer, the light may be provided only to a portion of the first preliminary insulating layer, which overlaps the mask opening.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a perspective view of a display device according to an embodiment of the invention;

FIG. 1B is an exploded perspective view of the display device according to an embodiment of the invention;

FIG. 2 is a cross-sectional view of a display panel according to an embodiment of the invention;

FIG. 3 is a plan view of a display panel according to an embodiment of the invention;

FIG. 4 is an enlarged plan view of a portion of a display region of the display panel according to an embodiment of the invention;

FIG. 5A is an enlarged cross-sectional view of a partial region of the display panel according to an embodiment of the invention;

FIG. 5B is an enlarged cross-sectional view of the display panel according to an embodiment of the invention, which illustrates a region AA′ of FIG. 5A;

FIG. 6A is an enlarged cross-sectional view of a portion of the display panel according to an embodiment of the invention;

FIG. 6B is an enlarged cross-sectional view of a portion of the display panel according to an embodiment of the invention;

FIG. 7 is an enlarged cross-sectional view of a partial region of the display panel according to an embodiment of the invention;

FIG. 8 is a cross-sectional view of the display panel according to an embodiment of the invention, which is taken along line I-I′ of FIG. 4;

FIG. 9A is a cross-sectional view illustrating some steps of a method of manufacturing the display panel according to an embodiment of the invention;

FIG. 9B is a cross-sectional view illustrating some steps of a method of manufacturing the display panel according to an embodiment of the invention;

FIG. 9C is a cross-sectional view illustrating some steps of a method of manufacturing the display panel according to an embodiment of the invention;

FIG. 9D is a cross-sectional view illustrating some steps of a method of manufacturing the display panel according to an embodiment of the invention;

FIG. 9E is a cross-sectional view illustrating some steps of a method of manufacturing the display panel according to an embodiment of the invention;

FIG. 9F is a cross-sectional view illustrating some steps of a method of manufacturing the display panel according to an embodiment of the invention;

FIG. 9G is a cross-sectional view illustrating some steps of a method of manufacturing the display panel according to an embodiment of the invention;

FIG. 9H is a cross-sectional view illustrating some steps of a method of manufacturing the display panel according to an embodiment of the invention;

FIG. 9I is a cross-sectional view illustrating some steps of a method of manufacturing the display panel according to an embodiment of the invention;

FIG. 10A is a cross-sectional view illustrating some steps of the method of manufacturing the display panel according to an embodiment of the invention;

FIG. 10B is a cross-sectional view illustrating some steps of the method of manufacturing the display panel according to an embodiment of the invention;

FIG. 10C is a cross-sectional view illustrating some steps of the method of manufacturing the display panel according to an embodiment of the invention;

FIG. 10D is a cross-sectional view illustrating some steps of the method of manufacturing the display panel according to an embodiment of the invention;

FIG. 10E is a cross-sectional view illustrating some steps of the method of manufacturing the display panel according to an embodiment of the invention;

FIG. 10F is a cross-sectional view illustrating some steps of the method of manufacturing the display panel according to an embodiment of the invention;

FIG. 10G is a cross-sectional view illustrating some steps of the method of manufacturing the display panel according to an embodiment of the invention;

FIG. 10H is a cross-sectional view illustrating some steps of the method of manufacturing the display panel according to an embodiment of the invention;

FIG. 10I is a cross-sectional view illustrating some steps of the method of manufacturing the display panel according to an embodiment of the invention;

FIG. 10J is a cross-sectional view illustrating some steps of the method of manufacturing the display panel according to an embodiment of the invention;

FIG. 10K is a cross-sectional view illustrating some steps of the method of manufacturing the display panel according to an embodiment of the invention;

FIG. 10L is a cross-sectional view illustrating some steps of the method of manufacturing the display panel according to an embodiment of the invention;

FIG. 11A is a cross-sectional view illustrating some steps of the method of manufacturing the display panel according to an embodiment of the invention;

FIG. 11B is a cross-sectional view illustrating some steps of the method of manufacturing the display panel according to an embodiment of the invention;

FIG. 11C is a cross-sectional view illustrating some steps of the method of manufacturing the display panel according to an embodiment of the invention; and

FIG. 11D is a cross-sectional view illustrating some steps of the method of manufacturing the display panel according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or region, layer, portion, etc.) is referred to as being related to another element such as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the present invention. Similarly, the second element may also be referred to as the first element. The terms of a singular form include plural forms unless otherwise specified.

The terminology used herein is for the purpose of describing particular embodiments only and is not intended to be limiting. As used herein, “a”, “an,” “the,” and “at least one” do not denote a limitation of quantity, and are intended to include the plural forms as well, unless the context clearly indicates otherwise. Within the Figures and the text of the disclosure, a reference number indicating a singular form of an element may also be used to reference a plurality of the singular element.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to the drawings.

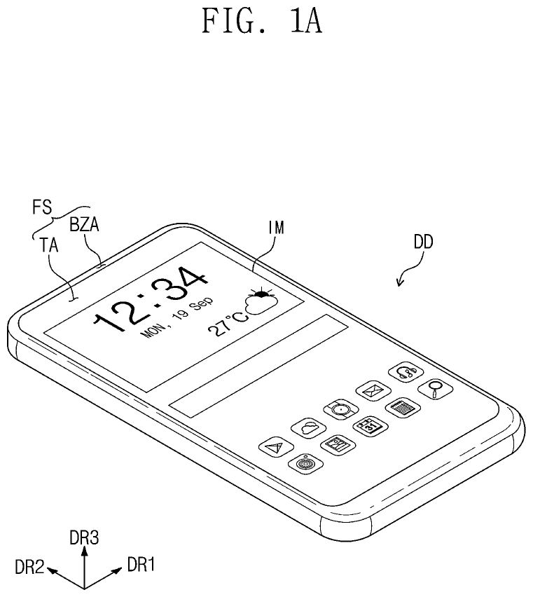

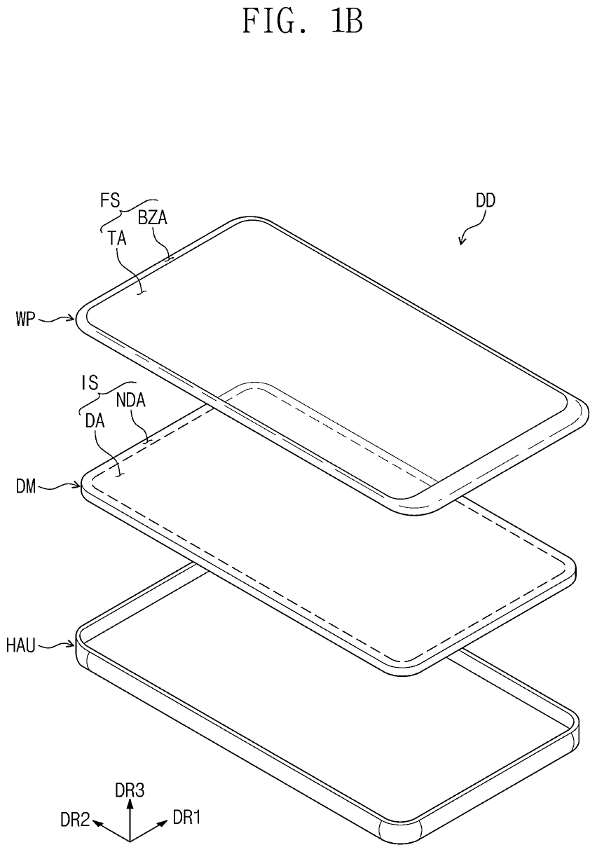

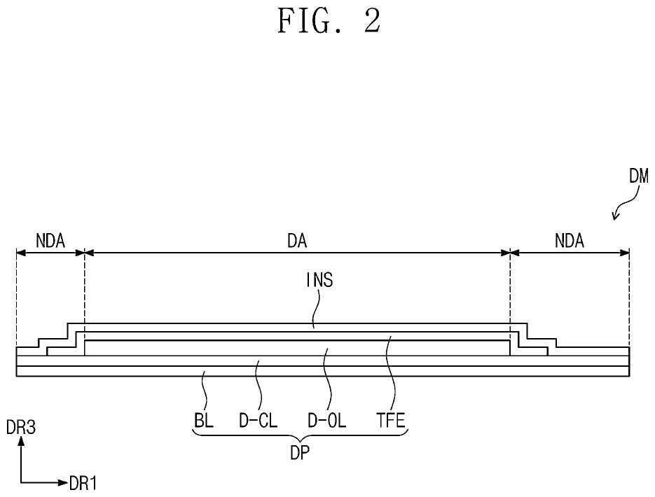

FIG. 1A is a perspective view of a display device according to an embodiment of the invention. FIG. 1B is an exploded perspective view of the display device according to an embodiment of the invention. FIG. 2 is a cross-sectional view of a display panel according to an embodiment of the invention.

In an embodiment of the invention, a display device DD may be a large electronic device such as a television, a monitor, and/or an external billboard. In addition, the display device DD may be a small or medium-sized electronic device such as a personal computer, a notebook computer, a personal digital terminal, a car navigation unit, a game machine, a smart phone, a tablet, and/or a camera. These are only presented as examples, and the display device DD may be applied to other electronic devices as long as they do not depart from the concept of the invention. In this embodiment, a smart phone is illustrated as an example of the display device DD.

In an embodiment and referring to FIGS. 1A, 1B, and 2, the display device DD may display an image IM toward a third direction DR3 on a display surface FS parallel to each of a first direction DR1 and a second direction DR2. The image IM may include a still image as well as a dynamic image. FIG. 1A illustrates a clock window and icons as an example of the image IM. The display surface FS on which the image IM is displayed may correspond to the front surface of the display device DD.

In an embodiment, the front surface (or upper surface) and the rear surface (or lower surface) of each member are defined based on a direction in which the image IM is displayed. The front surface and the rear surface may face away from each other in the third direction DR3, and a normal direction of each of the front surface and the rear surface may be parallel to the third direction DR3. Meanwhile, directions indicated by the first direction DR1, the second direction DR2, and the third direction DR3 are relative concepts and may be converted into other directions. In this specification, the expression “on a plane” may mean when viewed from the third direction DR3.

In an embodiment and as illustrated in FIG. 1B, the display device DD according to this embodiment may include a window WP, a display module DM, and a housing HAU. The window WP and the housing HAU may be coupled to each other to configure the exterior of the display device DD.

In an embodiment, the window WP may contain an optically transparent insulating material. For example, the window WP may contain glass and/or plastic. The front surface of the window WP may define the display surface FS of the display device DD. The display surface FS may include a transmission region TA and a bezel region BZA. The transmission region TA may be an optically transparent region. For example, the transmission region TA may have a visible light transmittance of about 90% or more.

In an embodiment, the bezel region BZA may have relatively low light transmittance compared to the transmission region TA. The bezel region BZA may define the shape of the transmission region TA. The bezel region BZA may be adjacent to and surround the transmission region TA. Meanwhile, this is illustrated as an example, and in the window WP according to an embodiment of the invention, the bezel region BZA may be omitted. The window WP may include at least any one functional layer of an anti-fingerprint layer, a hard coating layer, or an anti-reflection layer, and the invention is not limited to any one embodiment.

In an embodiment, the display module DM may be disposed below the window WP. The display module DM may substantially generate an image IM. The image IM generated by the display module DM is displayed on the display surface IS of the display module DM and is visually recognized by a user from the outside through the transmission region TA.

In an embodiment, the display module DM includes a display region DA and a non-display region NDA. The display region DA may be activated in response to an electrical signal. The non-display region NDA is adjacent to the display region DA. The non-display region NDA may surround the display region DA. The non-display region NDA is covered by the bezel region BZA and may not be visible from the outside.

In an embodiment and as illustrated in FIG. 2, the display module DM according to this embodiment may include a display panel DP and an input sensor INS. Although not separately illustrated, the display device DD according to an embodiment of the invention may further include a protection member disposed on the lower surface of the display panel DP and/or an anti-reflection member and/or a window member disposed on the upper surface of the input sensor INS.

In an embodiment, the display panel DP may be a light-emitting display panel and is not particularly limited thereto. For example, the display panel DP may be an organic light-emitting display panel and/or an inorganic light-emitting display panel. A light-emitting layer in the organic light-emitting display panel contains an organic light-emitting material. A light-emitting layer in the inorganic light-emitting display panel contains quantum dots, quantum rods, and/or micro LEDs. Hereinafter, the display panel DP will be described as an organic light-emitting display panel.

In an embodiment, the display panel DP may include a base layer BL, a circuit element layer D-CL disposed on the base layer BL, a display element layer D-OL, and an encapsulation layer TFE. The input sensor INS may be disposed directly on the encapsulation layer TFE. In this specification, the expression “Component A is disposed directly on component B” means that no adhesive layer is disposed between component A and component B.

In an embodiment, the base layer BL may include at least one plastic film. The base layer BL is a flexible substrate and may include a plastic substrate, a glass substrate, a metal substrate, and/or an organic/inorganic composite material substrate. In this embodiment, the display region DA and the non-display region NDA may be regarded as being defined in the base layer BL, and in this case, components disposed on the base layer BL may also be regarded as being disposed to overlap the display region DA and/or the non-display region NDA.

In an embodiment, the circuit element layer D-CL includes at least one insulating layer and a circuit element. The insulating layer includes at least one inorganic layer and at least one organic layer. The circuit element includes signal lines, a pixel driving circuit, and the like.

In an embodiment, the display element layer D-OL includes a partition wall and a light-emitting element. The light-emitting element may include an anode, a light-emitting pattern, and a cathode, and the light-emitting pattern may include at least a light-emitting layer.

In an embodiment, the encapsulation layer TFE includes a plurality of thin films. Some thin films are disposed to improve optical efficiency, and some other thin films are disposed to protect organic light-emitting diodes.

In an embodiment, the input sensor INS acquires the coordinate information of an external input. The input sensor INS may have a multi-layered structure. The input sensor INS may include a single conductive layer or a plurality of conductive layers. The input sensor INS may include a single insulating layer or a plurality of insulating layers. The input sensor INS may sense an external input, for example, in a capacitive manner. In this invention, the operation manner of the input sensor INS is not particularly limited thereto, and in an embodiment of the invention, the input sensor INS may sense an external input in an electromagnetic induction manner and/or a pressure-sensing manner. Meanwhile, in another embodiment of the invention, the input sensor INS may be omitted.

In an embodiment, as illustrated in FIG. 1B, the housing HAU may be coupled to the window WP to provide a predetermined inner space. The display module DM may be accommodated in the inner space.

In an embodiment, the housing HAU may contain a material with relatively high rigidity. For example, the housing HAU may include a plurality of frames and/or plates made of glass, plastic, or metal, and/or a combination thereof. The housing HAU may stably protect the components of the display device DD accommodated in the inner space from an external impact.

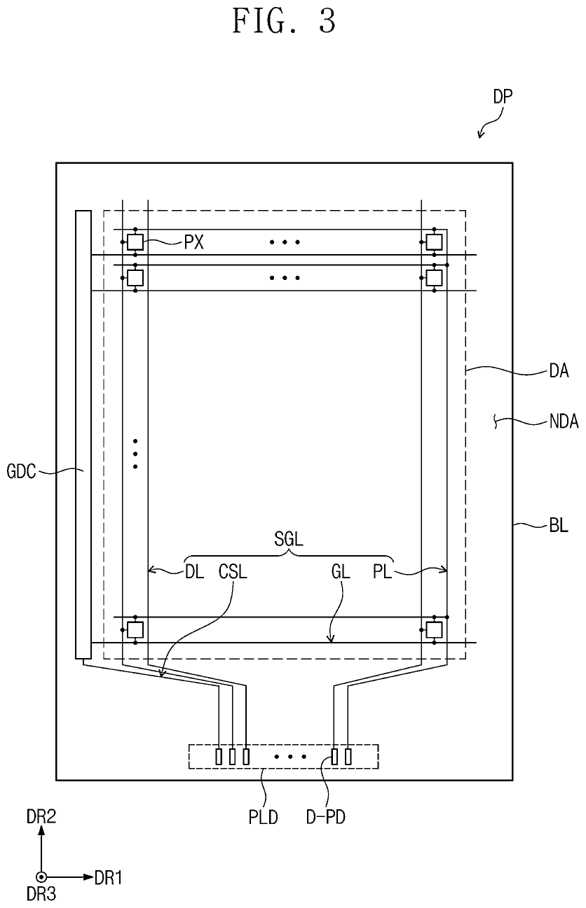

FIG. 3 is a plan view of a display panel according to an embodiment of the invention.

In an embodiment and referring to FIG. 3, the display panel DP may include a base layer BL divided into a display region DA and a non-display region NDA described with reference to FIG. 2.

In an embodiment, the display panel DP may include pixels PX disposed in the display region DA and signal lines SGL electrically connected to the pixels PX. The display panel DP may include a driving circuit GDC and a pad portion PLD disposed in the non-display region NDA.

In an embodiment, the pixels PX may be arranged in the first and second directions DR1 and DR2. The pixels PX may include a plurality of pixel rows extending in the first direction DR1 and arranged in the second direction DR2 and a plurality of pixel columns extending in the second direction DR2 and arranged in the first direction DR1.

In an embodiment, the signal lines SGL may include gate lines GL, data lines DL, a power line PL, and a control signal line CSL. Each of the gate lines GL may be connected to a corresponding pixel of the pixels PX, and each of the data lines DL may be connected to a corresponding pixel of the pixels PX. The power line PL may be electrically connected to the pixels PX. The control signal line CSL may be connected to the driving circuit GDC to provide control signals to the driving circuit GDC.

In an embodiment, the driving circuit GDC may include a gate driving circuit. The gate driving circuit may generate gate signals and sequentially output the generated gate signals to the gate lines GL. The gate driving circuit may further output another control signal to the pixel driving circuit.

In an embodiment, the pad portion PLD may be connected to a flexible circuit board. The pad portion PLD may include pixel pads D-PD, and the pixel pads D-PD may connect the flexible circuit board to the display panel DP. Each of the pixel pads D-PD may be connected to a corresponding signal line of the signal lines SGL. The pixel pads D-PD may be connected to corresponding pixels PX through the signal lines SGL. In addition, any one of the pixel pads D-PD may be connected to the driving circuit GDC.

In addition, in an embodiment, the pad portion PLD may further include input pads. The input pads may connect the flexible circuit board to the input sensor INS (see FIG. 2). Without being limited thereto, however, the input pads may be disposed on the input sensor INS (see FIG. 2) and connected to the pixel pads D-PD and a separate circuit board. Alternatively, the input sensor (INS, see FIG. 2) may be omitted and may not further include the input pads.

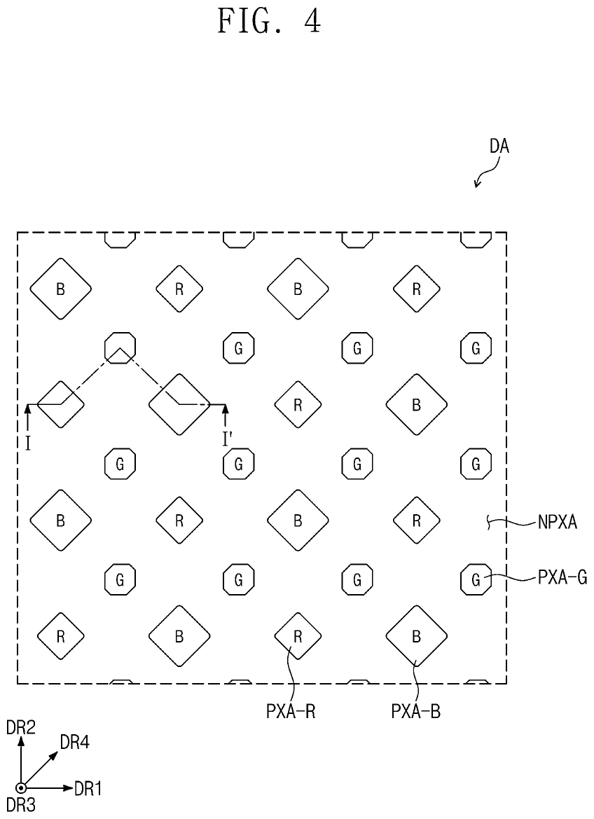

FIG. 4 is an enlarged plan view of a portion of the display region of the display panel according to an embodiment of the invention. FIG. 4 illustrates a plane of the display module DM (see FIG. 2) viewed from the display surface IS (see FIG. 2) of the display module DM (see FIG. 2) and shows an arrangement of light-emitting regions PXA-R, PXA-G, and PXA-B, in accordance with an embodiment.

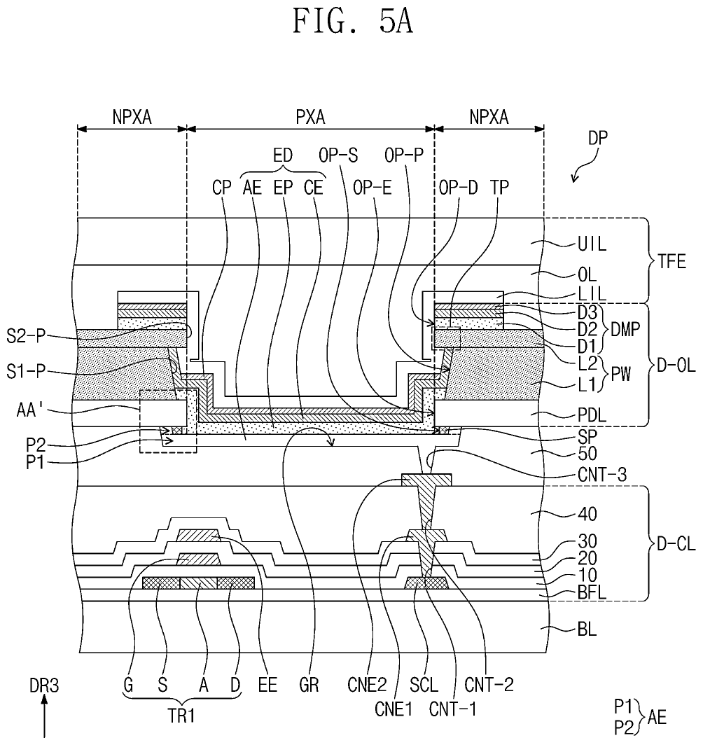

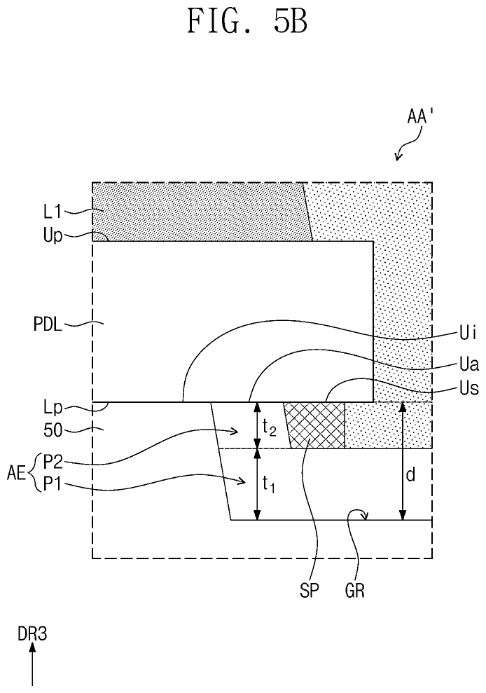

In an embodiment and referring to FIG. 4, the display region DA may include a first light-emitting region PXA-R, a second light-emitting region PXA-G, and a third light-emitting region PXA-B, and a peripheral region NPXA surrounding the first light-emitting region PXA-R, the second light-emitting region PXA-G, and the third light-emitting region PXA-B. The first light-emitting region PXA-R, the second light-emitting region PXA-G, and the third light-emitting region PXA-B may respectively correspond to regions in which light provided from light-emitting elements ED1, ED2, and ED3 (see FIG. 5A) is emitted. The first light-emitting region PXA-R, the second light-emitting region PXA-G, and the third light-emitting region PXA-B may be classified according to the color of the light emitted toward the outside of the display module DM (see FIG. 2).

In an embodiment, the first light-emitting region PXA-R, the second light-emitting region PXA-G, and the third light-emitting region PXA-B may respectively provide first to third color lights having different colors. For example, the first color light may be red light, the second color light may be green light, and the third color light may be blue light. However, the first to third color lights are not necessarily limited to the above examples.

In an embodiment, each of the first light-emitting region PXA-R, the second light-emitting region PXA-G, and the third light-emitting region PXA-B may be defined as a region in which an upper surface of the anode is exposed by a light-emitting opening which will be described later. The peripheral region NPXA sets boundaries between the first light-emitting region PXA-R, the second light-emitting region PXA-G, and the third light-emitting region PXA-B and prevents color mixing between the first light-emitting region PXA-R, the second light-emitting region PXA-G, and the third light-emitting region PXA-B.

In an embodiment, each of the first light-emitting region PXA-R, the second light-emitting region PXA-G, and the third light-emitting region PXA-B may be provided in plurality and they may be repeatedly disposed in a predetermined arrangement form in the display region DA. For example, the first light-emitting region PXA-R, the second light-emitting region PXA-G, and the third light-emitting region PXA-B may be alternately arranged along the first direction DR1 to form a ‘first group’. The second light-emitting regions PXA-G may be arranged along the first direction DR1 to form a ‘second group’. Each of the ‘first group’ and the ‘second group’ may be provided in plurality, and the ‘first groups’ and the ‘second groups’ may be alternately arranged along the second direction DR2.

In an embodiment, one second light-emitting region PXA-G may be disposed to be spaced apart from one first light-emitting region PXA-R or one third light-emitting region PXA-B in a fourth direction DR4. The fourth direction DR4 may be defined as a direction between the first and second directions DR1 and DR2.

Meanwhile, in an embodiment, FIG. 4 exemplarily illustrates an arrangement form of the first light-emitting region PXA-R, the second light-emitting region PXA-G, and the third light-emitting region PXA-B but the arrangement form thereof is not limited thereto and they may be arranged in various forms. In an embodiment of the invention, the first light-emitting region PXA-R, the second light-emitting region PXA-G, and the third light-emitting region PXA-B may have a PENTILE™ arrangement form as illustrated in FIG. 4. Alternatively, the first light-emitting region PXA-R, the second light-emitting region PXA-G, and the third light-emitting region PXA-B may have a stripe arrangement form or a Diamond Pixel™ arrangement form.

In an embodiment, the first light-emitting region PXA-R, the second light-emitting region PXA-G, and the third light-emitting region PXA-B may have various shapes on a plane. For example, the first light-emitting region PXA-R, the second light-emitting region PXA-G, and the third light-emitting region PXA-B may have polygonal, circular, or elliptical shapes. FIG. 4 exemplarily illustrates, on a plane, the first light-emitting region PXA-R and the third light-emitting region PXA-B having a quadrangular shape (or a diamond shape) and the second light-emitting region PXA-G having an octagonal shape.

In an embodiment, the first light-emitting region PXA-R, the second light-emitting region PXA-G, and the third light-emitting region PXA-B may have a same shape on a plane, or at least some of them may have different shapes. FIG. 4 exemplarily illustrates, on a plane, the first light-emitting region PXA-R and the third light-emitting region PXA-B having a same shape and the second light-emitting region PXA-G having a shape different from those of the first light-emitting region PXA-R and the third light-emitting region PXA-B.

In an embodiment, at least some of the first light-emitting region PXA-R, the second light-emitting region PXA-G, and the third light-emitting region PXA-B may have different areas on a plane. In an embodiment of the invention, the area of the first light-emitting region PXA-R configured to emit red light may be larger than the area of the second light-emitting region PXA-G configured to emit green light and smaller than the area of the third light-emitting region PXA-B configured to emit blue light. However, the size relationship between the areas of the first light-emitting region PXA-R, the second light-emitting region PXA-G, and the third light-emitting region PXA-B according to the color of emitted light is not limited thereto and may vary depending on the design of the display module DM (see FIG. 2). In addition, without being limited thereto, the first light-emitting region PXA-R, the second light-emitting region PXA-G, and the third light-emitting region PXA-B may have a same area on a plane.

Meanwhile, in an embodiment, the shape, area, and arrangement of the first light-emitting region PXA-R, the second light-emitting region PXA-G, and the third light-emitting region PXA-B of the display module DM (see FIG. 2) according to this invention may be designed in various ways according to the color of emitted light and/or the size and/or configuration of the display module DM (see FIG. 2), and the invention is not limited to the embodiment illustrated in FIG. 4.

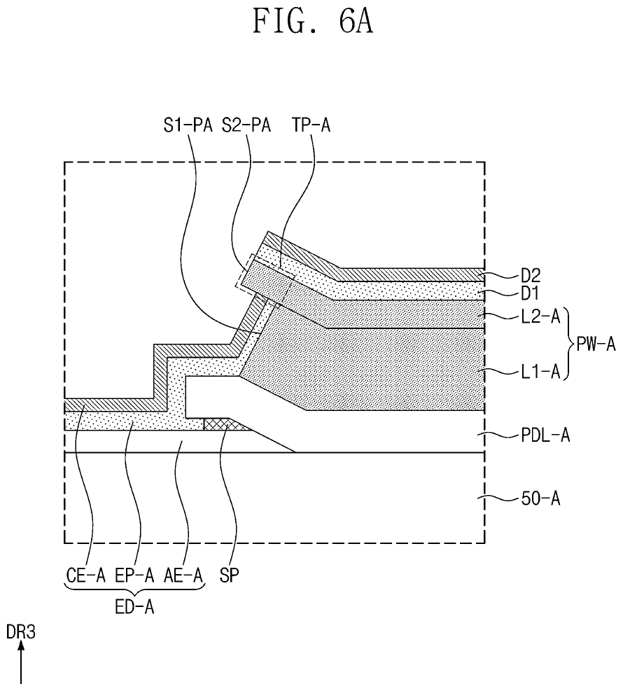

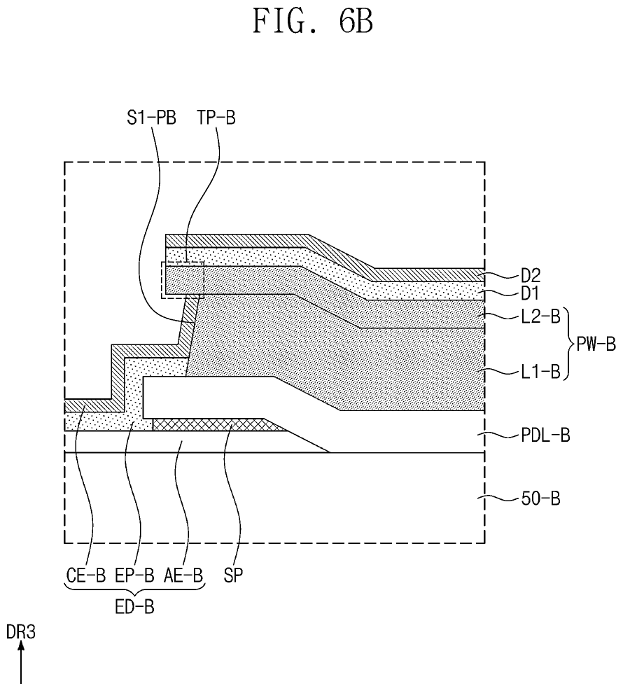

FIG. 5A is an enlarged cross-sectional view of a partial region of the display panel according to an embodiment of the invention. FIG. 5B is an enlarged cross-sectional view of the display panel according to an embodiment of the invention, which illustrates a region AA′ of FIG. 5A. FIGS. 6A and 6B are enlarged cross-sectional views of a portion of the display panel according to a comparative embodiment of the invention.

In an embodiment, FIG. 5A is an enlarged view of one light-emitting region PXA in the display region DA (see FIG. 3), and the light-emitting region PXA of FIG. 5A may correspond to any one of the first light-emitting region PXA-R, the second light-emitting region PXA-G, and the third light-emitting region PXA-B of FIG. 4. Referring to FIGS. 5A and 5B, the display panel DP may include a base layer BL, a circuit element layer D-CL, a fifth insulating layer 50, a display element layer D-OL, and/or a thin film encapsulation layer TFE.

In an embodiment, the display panel DP may include a plurality of insulating layers, a semiconductor pattern, a conductive pattern, a signal line, and the like. An insulating layer, a semiconductor layer, and a conductive layer are formed by a method such as coating or deposition. Hereafter, the insulating layer, the semiconductor layer, and/or the conductive layer may be selectively patterned through photolithography and etching processes. In this way, the semiconductor pattern, the conductive pattern, the signal line, and the like, which are included in the circuit element layer D-CL and the display element layer D-OL, may be formed.

In an embodiment, the circuit element layer D-CL may be disposed on the base layer BL. The circuit element layer D-CL may include a buffer layer BFL, a transistor TR1, a signal transmission region SCL, first to fourth insulating layers 10, 20, 30, and 40, respectively, an electrode EE, and a plurality of connection electrodes CNE1 and CNE2.

In an embodiment, the buffer layer BFL may be disposed on the base layer BL. The buffer layer BFL may improve bonding strength between the base layer BL and the semiconductor pattern. The buffer layer BFL may include a silicon oxide layer and/or a silicon nitride layer. The silicon oxide layer and the silicon nitride layer may be alternately stacked on each other.

In an embodiment, the semiconductor pattern may be disposed on the buffer layer BFL. The semiconductor pattern may contain polysilicon. Without being limited thereto, however, the semiconductor pattern may contain amorphous silicon and/or metal oxide. FIG. 5A illustrates only a portion of the semiconductor pattern, and the semiconductor pattern may be further disposed in the plurality of light-emitting regions PXA-R, PXA-G, and PXA-B (see FIG. 4). The semiconductor pattern may be arranged in a specific rule across the plurality of light-emitting regions PXA-R, PXA-G, and PXA-B (see FIG. 4). The semiconductor pattern may have different electrical properties depending on whether it is doped or not. The semiconductor pattern may include a first region having a high doping concentration and a second region having a low doping concentration. The first region may be doped with an N-type dopant or a P-type dopant. A P-type transistor may include the first region doped with a P-type dopant.

In an embodiment, the first region has higher conductivity than the second region and substantially serves as an electrode or signal line. The second region may substantially correspond to an active (or channel) of a transistor. In other words, a portion of the semiconductor pattern may be an active of a transistor, another portion thereof may be a source or drain of a transistor, and still another portion thereof may be a conductive region.

In an embodiment, a source S, an active A, and a drain D of the transistor TR1 may be formed from the semiconductor pattern. FIG. 5A illustrates a portion of the signal transmission region SCL formed from the semiconductor pattern. Although not separately illustrated, the signal transmission region SCL may be connected to the drain D of the transistor TR1 on a plane.

In an embodiment, the first to fourth insulating layers 10 to 40, respectively, may be disposed above the buffer layer BFL. The first to fourth insulating layers 10 to 40, respectively, may be inorganic layers and/or organic layers.

In an embodiment, the first insulating layer 10 may be disposed on the buffer layer BFL. A gate G may be disposed on the first insulating layer 10. The second insulating layer 20 may be disposed on the first insulating layer 10 to cover the gate G. An electrode EE may be disposed on the second insulating layer 20. The third insulating layer 30 may be disposed on the second insulating layer 20 to cover the electrode EE.

In an embodiment, the first connection electrode CNE1 may be disposed on the third insulating layer 30. The first connection electrode CNE1 may be connected to the signal transmission region SCL through a contact hole CNT-1 passing through the first to third insulating layers 10 to 30, respectively. The fourth insulating layer 40 may be disposed on the third insulating layer 30 to cover the first connection electrode CNE1. The fourth insulating layer 40 may be an organic layer.

In an embodiment, the second connection electrode CNE2 may be disposed on the fourth insulating layer 40. The second connection electrode CNE2 may be connected to the first connection electrode CNE1 through a contact hole CNT-2 passing through the fourth insulating layer 40.

In an embodiment, the fifth insulating layer 50 may be disposed on the fourth insulating layer 40. The fifth insulating layer 50 may cover the second connection electrode CNE2. The fifth insulating layer 50 may be an organic layer. In this embodiment, the fifth insulating layer 50 may be composed of a single film.

According to this embodiment, a groove GR may be defined in the fifth insulating layer 50. The groove GR may be formed by removing a portion of the fifth insulating layer 50 from the upper surface of the fifth insulating layer 50. According to this embodiment, the groove GR of the fifth insulating layer 50 may provide a space in which an anode AE, which will be described later, may be disposed, and therefore, it is possible to prevent a step difference from being formed between components disposed on the fifth insulating layer 50. Through this, it is possible to prevent a defective light-emitting element ED from being formed and provide the display panel DP with increased display efficiency by increasing a light-emitting aperture ratio, and it is also possible to provide the display panel DP with an improved degree of design freedom. A detailed description of this will be given later.

In an embodiment, the display element layer D-OL may be disposed on the fifth insulating layer 50. The display element layer D-OL may include a light-emitting element ED, a sacrificial pattern SP, a pixel defining layer PDL, a partition wall PW, and dummy patterns DMP.

In an embodiment, the light-emitting element ED may include an anode AE (or first electrode), a light-emitting pattern EP, and a cathode CE (or second electrode). First to third light-emitting elements disposed respectively corresponding to the aforementioned first light-emitting region PXA-R, the aforementioned second light-emitting region PXA-G, and the aforementioned third light-emitting region PXA-B (see FIG. 4) may have substantially the same configuration as the light-emitting element ED of FIG. 5A. The descriptions of the anode AE, the light-emitting pattern EP, and the cathode CE may be equally applied to all of the anode, the light-emitting pattern, and the cathode of each of the first to third light-emitting elements.

According to this invention, the anode AE may be disposed in the groove GR of the fifth insulating layer 50. The anode AE may be a transmissive electrode, a semi-transmissive electrode, or a reflective electrode. The anode AE may have conductivity. For example, the anode AE may be formed of various materials, such as metal, transparent conductive oxide (TCO), or a conductive polymer material, as long as they have conductivity. The anode AE may be connected to the second connection electrode CNE2 through a connection contact hole CNT-3 defined to pass through the fifth insulating layer 50. Accordingly, the anode AE may be electrically connected to the signal transmission region SCL through the first and second connection electrodes CNE1 and CNE2 so as to be electrically connected to a corresponding circuit element.

In an embodiment, the anode AE may include a first portion P1 and a second portion P2 extending from the first portion P1 toward the pixel defining layer PDL. The second portion P2 may be provided in a closed-line shape corresponding to the outer portion of the groove GR on a plane.

In an embodiment, the thickness of the anode AE may be smaller than or equal to a depth d of the groove GR. Specifically, a thickness t1 of the first portion P1 of the anode AE may be smaller than the depth d of the groove GR, and the maximum value of the sum of the thickness t1 of the first portion P1 and a thickness t2 of the second portion P2 may be substantially equal to the depth d of the groove GR.

In an embodiment, the sacrificial pattern SP may be disposed in the groove GR of the fifth insulating layer 50. The sacrificial pattern SP may be disposed on the first portion P1 of the anode AE and surrounded by the second portion P2. A sacrificial opening OP-S exposing a portion of the upper surface of the first portion P1 may be defined in the sacrificial pattern SP. In an embodiment of the invention, the sacrificial pattern SP may contain amorphous transparent conductive oxide.

In an embodiment, an upper surface Us of the sacrificial pattern SP and an upper surface Ui of the fifth insulating layer 50 may be substantially coplanar with each other. In addition, an upper surface Ua of the second portion P2 of the anode AE may be substantially coplanar with each of the upper surface Us of the sacrificial pattern SP and the upper surface Ui of the fifth insulating layer 50. The sum of the thickness of the sacrificial pattern SP and the thickness t1 of the first portion P1 of the anode AE may be substantially equal to the depth d of the groove GR.

In an embodiment, the pixel defining layer PDL may be disposed on the fifth insulating layer 50. A light-emitting opening OP-E may be defined in the pixel defining layer PDL. The pixel defining layer PDL may expose at least a portion of the anode AE through the light-emitting opening OP-E.

In addition, in an embodiment, the light-emitting opening OP-E may correspond to the sacrificial opening OP-S. According to an embodiment, the upper surface of the first portion P1 of the anode AE may be spaced apart from the pixel defining layer PDL on a cross section with the sacrificial pattern SP interposed therebetween, and therefore, it is possible to protect the anode AE from being damaged in a forming process of the light-emitting opening OP-E. Meanwhile, in this specification, the expression “A region/portion corresponds to another region/portion.” means that they overlap each other, but the expression is not limited to having a same area.

In an embodiment, an a plane, the area of the light-emitting opening OP-E may be smaller than that of the sacrificial opening OP-S. That is, the inner side surface of the pixel defining layer PDL defining the light-emitting opening OP-E may be closer to the center of the anode AE than the inner side surface of the sacrificial pattern SP defining the sacrificial opening OP-S. Without being limited thereto, however, the inner side surface of the sacrificial pattern SP defining the sacrificial opening OP-S may be substantially aligned with the inner side surface of the pixel defining layer PDL defining a corresponding light-emitting opening OP-E. In this case, the light-emitting region PXA may be regarded as a region of the anode AE exposed through a corresponding sacrificial opening OP-S.

In an embodiment, the pixel defining layer PDL may contain an inorganic insulating material. For example, the pixel defining layer PDL may contain silicon oxide, silicon nitride, or a combination thereof. Through this, it is possible to prevent moisture from being discharged from the pixel defining layer PDL in a subsequent patterning process. The pixel defining layer PDL may be disposed between the anode AE and the partition wall PW to block electrical connection between the anode AE and the partition wall PW.

In an embodiment, each of the upper and lower surfaces Up and Lp of the pixel defining layer PDL may be generally flat. The upper surface Up and the lower surface Lp of the pixel defining layer PDL may have a generally constant thickness. According to an embodiment, as the groove GR of the fifth insulating layer 50 provides a space in which the anode AE and the sacrificial pattern SP may be disposed, a base surface on which the pixel defining layer PDL is disposed may be provided to be flat. Accordingly, no step difference may be formed on the pixel defining layer PDL and therefore, the pixel defining layer PDL may be provided to be generally flat.

In an embodiment, the partition wall PW (or conductive partition wall) may be disposed on the pixel defining layer PDL. A partition wall opening OP-P may be defined in the partition wall PW. The partition wall opening OP-P may correspond to the light-emitting opening OP-E and may expose at least a portion of the anode AE.

In an embodiment, the partition wall PW may have an undercut shape on a cross section. The partition wall PW may include a plurality of layers sequentially stacked, and at least one layer of the plurality of layers may be recessed, compared to adjacent stacked layers. Accordingly, the partition wall PW may include a tip portion TP.

In an embodiment, the partition wall PW may include a first layer L1 and a second layer L2. The first layer L1 may be disposed on the pixel defining layer PDL, and the second layer L2 may be disposed on the first layer L1. The first layer L1 may have a first conductivity, and the second layer L2 may have a second conductivity. In an embodiment, the first conductivity may be higher than the second conductivity, and the thickness of the first layer L1 may be greater than the thickness of the second layer L2. The etch rate of the first layer L1 may be greater than that of the second layer L2.

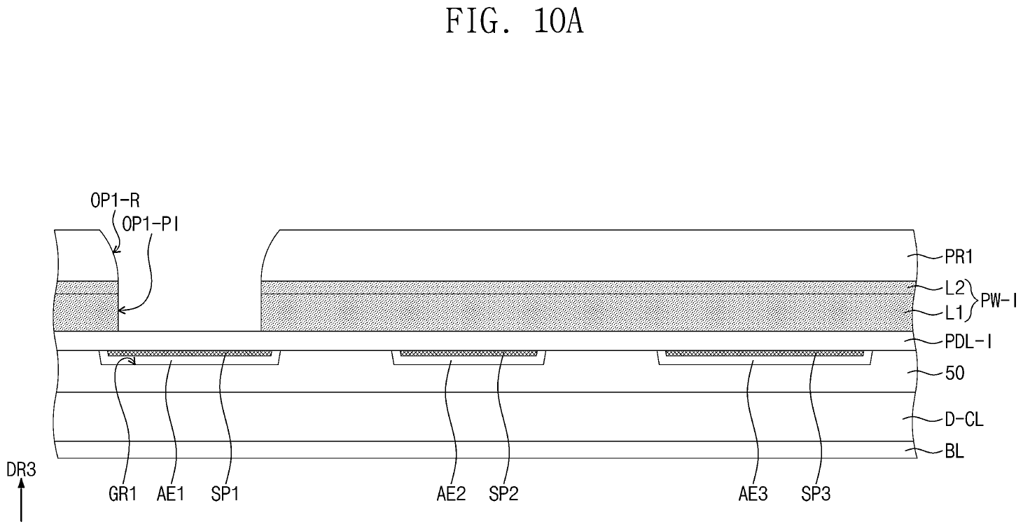

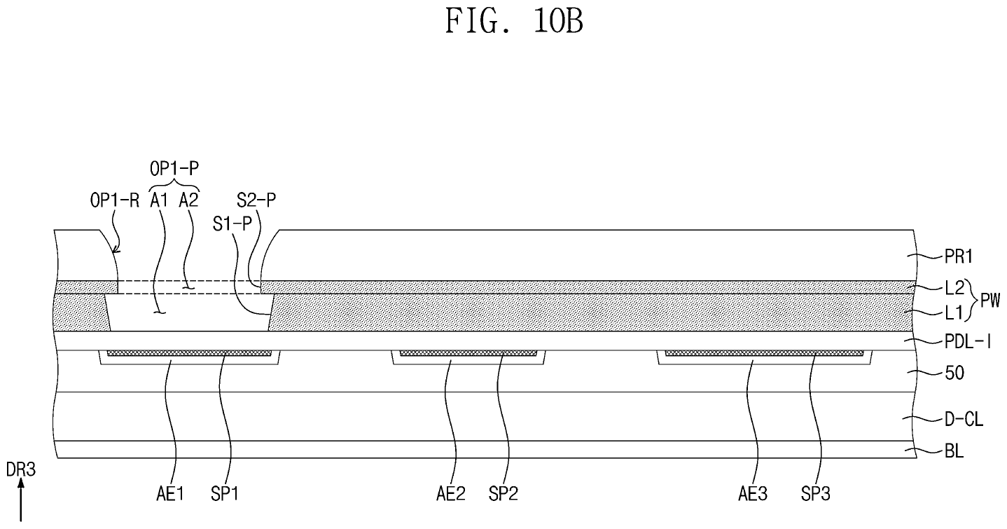

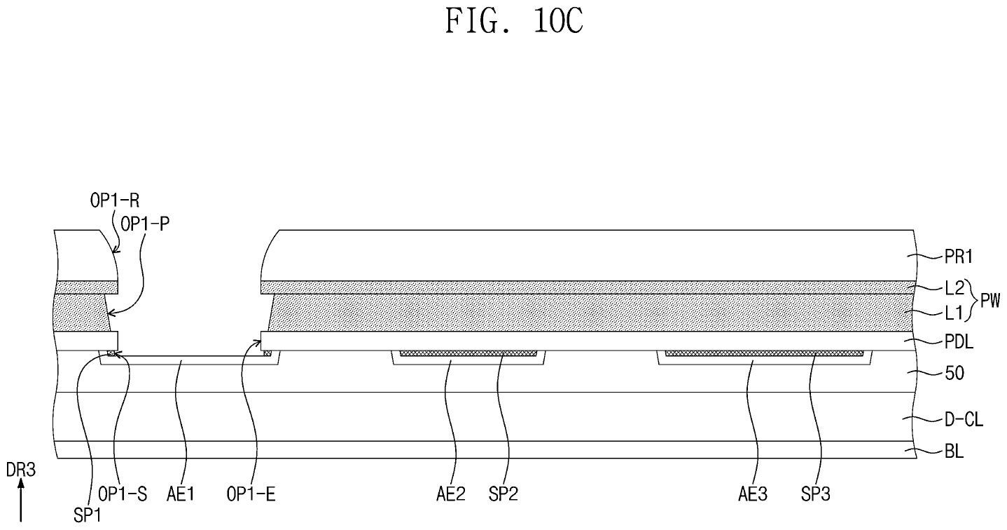

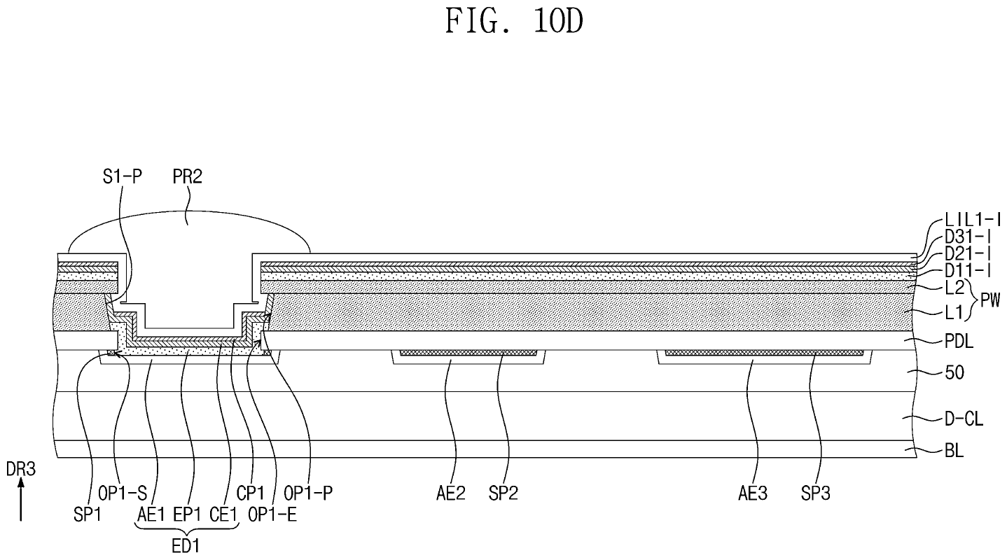

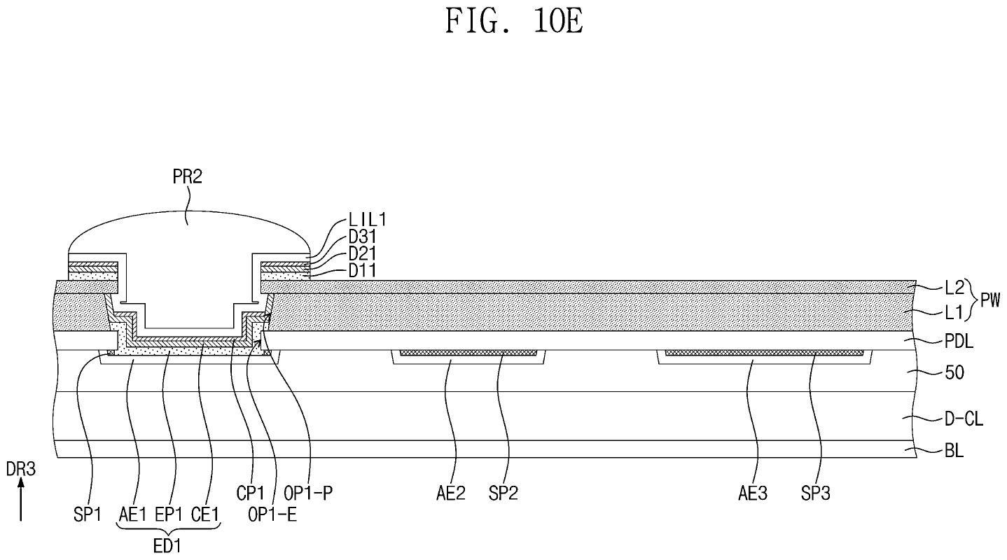

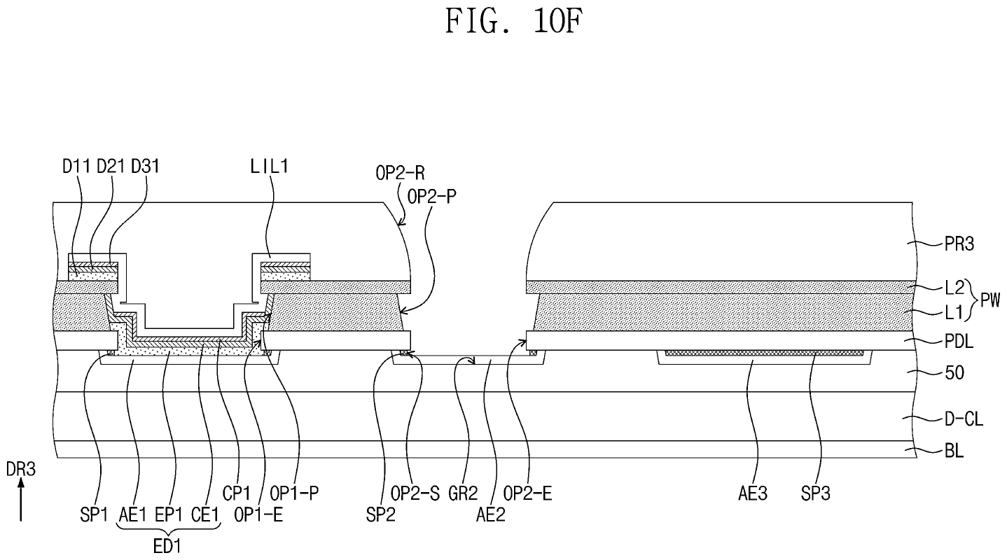

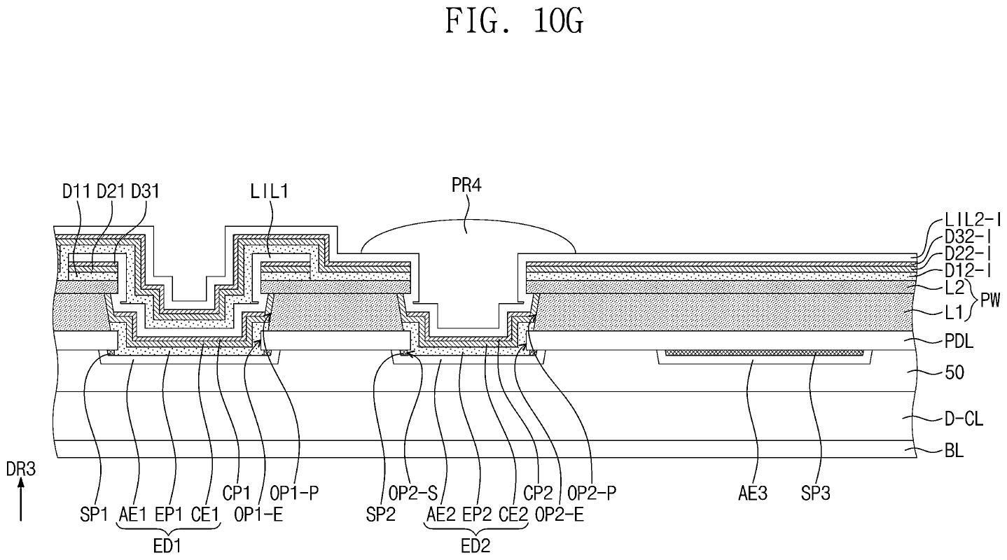

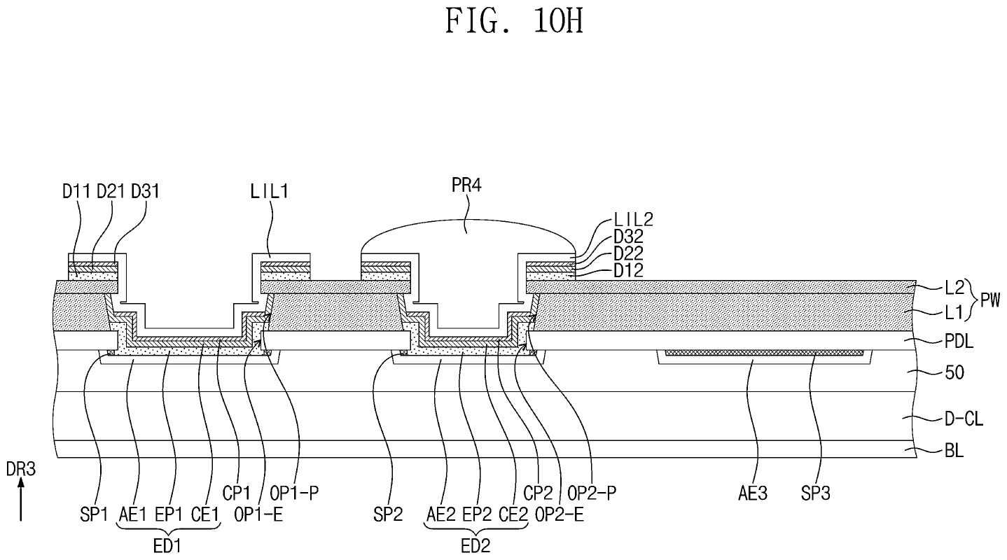

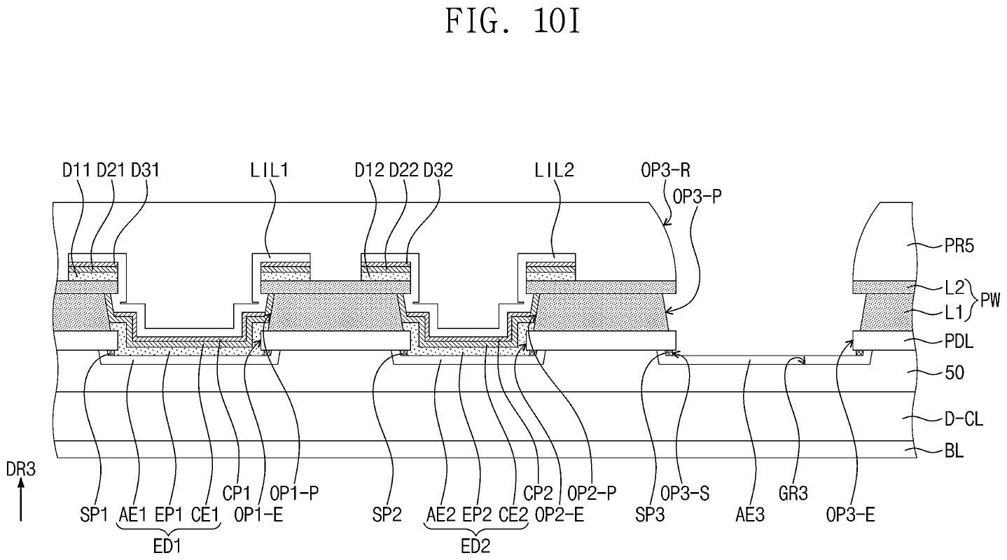

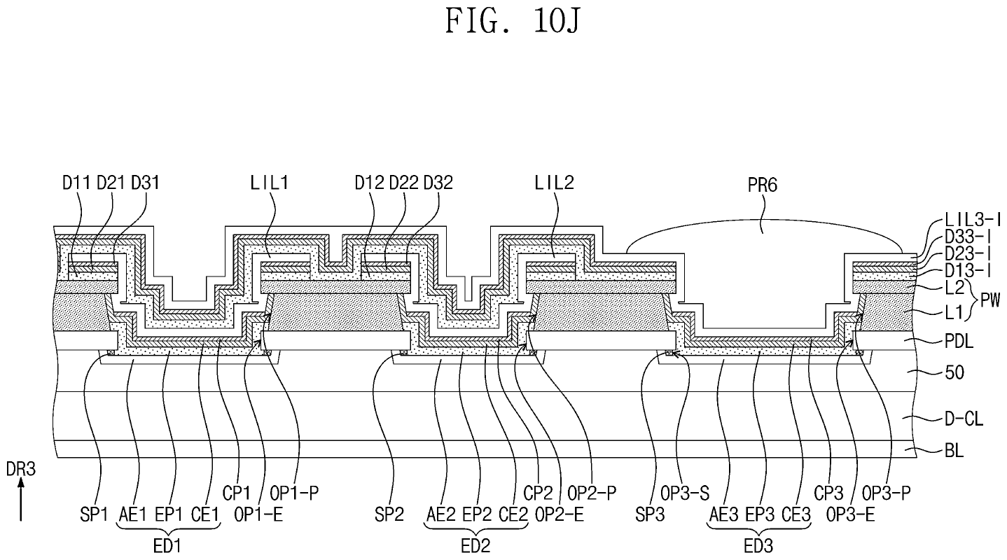

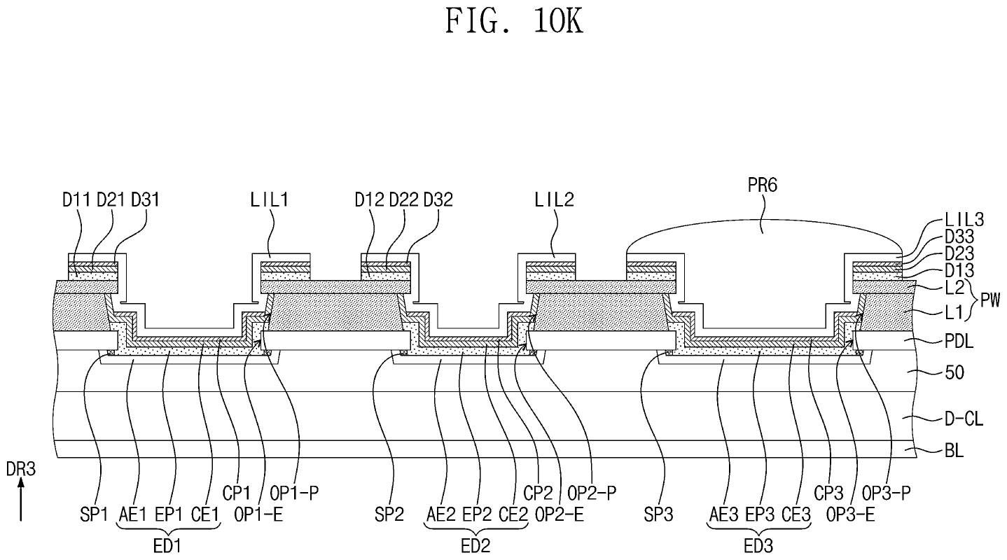

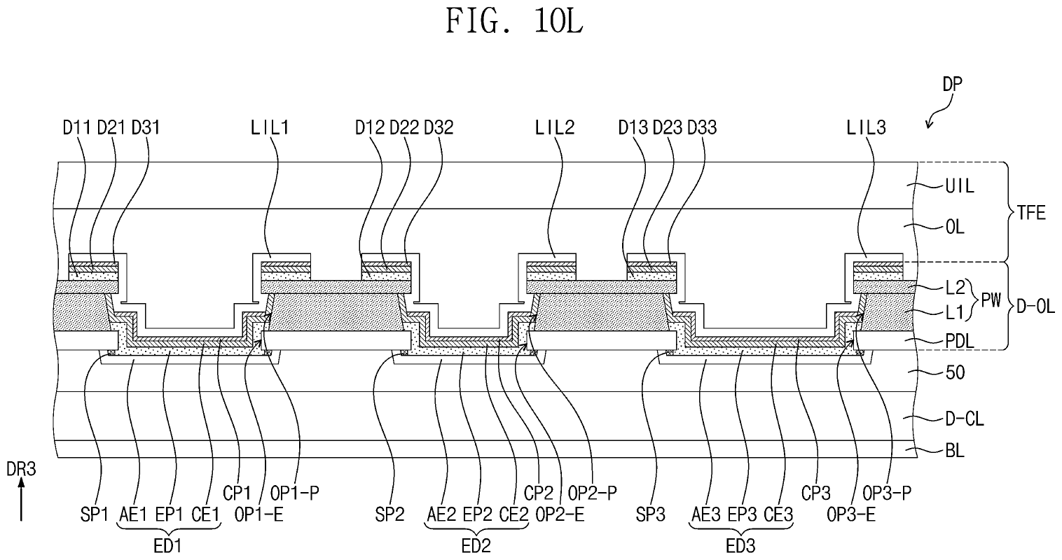

In an embodiment, the first layer L1 may be relatively recessed compared to the second layer L2 with respect to the light-emitting region PXA. That is, the first layer L1 may be formed by undercutting the second layer L2. The partition wall opening OP-P defined in the partition wall PW may include a first region A1 (see FIG. 10B) and a second region A2 (see FIG. 10B) sequentially arranged in the third direction DR3. The first layer L1 may include a first inner side surface S1-P defining the first region A1 (see FIG. 10B) of the partition wall opening OP-P, and the second layer L2 may include a second inner side surface S2-P defining the second region A2 (see FIG. 10B) of the partition wall opening OP-P.

In an embodiment, the first inner side surface S1-P of the first layer L1 may be disposed relatively more inward than the second inner side surface S2-P of the second layer L2 with respect to the light-emitting region PXA. That is, the first inner side surface S1-P may be disposed to be recessed from the second inner side surface S2-P with respect to the light-emitting region PXA. That is, the first inner side surface S1-P may be formed by undercutting the second inner side surface S2-P. A portion of the second layer L2 protruding from the first layer L1 toward the light-emitting region PXA may define a tip portion TP.

Meanwhile, in an embodiment, FIG. 5A exemplarily illustrates that the first inner side surface S1-P of the first layer L1 has a tapered shape with respect to the upper surface of the pixel defining layer PDL, but the invention is not limited thereto, and the first inner side surface S1-P may be perpendicular to the upper surface of the pixel defining layer PDL.

In an embodiment of the invention, the first layer L1 may contain a conductive material. The conductive material may include metal, transparent conductive oxide (TCO), and/or a combination thereof. For example, the metal may include gold (Au), silver (Ag), aluminum (Al), magnesium (Mg), lithium (Li), molybdenum (Mo), titanium (Ti), copper (Cu), and/or an alloy. The transparent conductive oxide may include indium tin oxide (ITO), indium zinc oxide (IZO), zinc oxide, indium oxide, indium gallium oxide, indium gallium zinc oxide (IGZO) and/or aluminum zinc oxide.

In an embodiment of the invention, the second layer L2 may include metal, metal oxide, metal nitride, and/or non-metal. For example, the metal includes gold (Au), silver (Ag), aluminum (Al), magnesium (Mg), lithium (Li), molybdenum (Mo), titanium (Ti), copper (Cu), and/or an alloy. The metal oxide may include transparent conductive oxide (TCO). The non-metal may include silicon (Si), silicon oxide (SiOx), silicon nitride (SiNx), silicon oxynitride (SiON), metal oxide, metal nitride, and/or a combination thereof.

In an embodiment, each of the first layer L1 and the second layer L2 of the partition wall PW may be generally flat. In particular, since no step difference is formed in the second layer L2, the lifting phenomenon of the tip portion TP may be prevented. A detailed description of this will be given later.

In an embodiment, the light-emitting pattern EP may be disposed on the anode AE. The light-emitting pattern EP may include a light-emitting layer containing a light-emitting material. The light-emitting pattern EP may further include a hole injection layer (HIL) and a hole transport layer (HTL), which are disposed between the anode AE and the light-emitting layer, and may further include an electron transport layer (ETL) and an electron injection layer (EIL) which are disposed on the light-emitting layer. The light-emitting pattern EP may also be referred to as an ‘organic layer’ or an ‘intermediate layer’.

In an embodiment, the light-emitting pattern EP may be patterned by the tip portion TP defined in the partition wall PW. At least a portion of the light-emitting pattern EP may be disposed inside the sacrificial opening OP-S in the groove GR and the light-emitting opening OP-E. As illustrated in FIG. 5A, the light-emitting pattern EP may be disposed inside the sacrificial opening OP-S, the light-emitting opening OP-E, and the partition wall opening OP-P. The light-emitting pattern EP may cover a portion of the upper surface of the pixel defining layer PDL, which is exposed through the partition wall opening OP-P. Without being limited thereto, however, the light-emitting pattern EP may not be disposed inside the partition wall opening OP-P.

In an embodiment, the cathode CE may be disposed on the light-emitting pattern EP. The cathode CE may be patterned by the tip portion TP defined in the partition wall PW. The cathode CE may come in contact with the first inner side surface S1-P of the first layer L1. At least a portion of the cathode CE may be disposed in the partition wall opening OP-P. As illustrated in FIG. 5A, the cathode CE may be disposed in the partition wall opening OP-P and the light-emitting opening OP-E. Without being limited thereto, however, the cathode CE may be disposed only in the partition wall opening OP-P depending on the thickness of the light-emitting pattern EP and/or the thickness of the pixel defining layer PDL. The cathode CE may have conductivity. For example, the cathode CE may be formed of various materials, such as metal, transparent conductive oxide (TCO), and/or a conductive polymer material, as long as they have conductivity.

In an embodiment, the partition wall PW may receive a bias voltage. As the cathodes CE comes in direct contact with the partition wall PW, the cathode CE may be electrically connected to the partition wall PW and receive a bias voltage. According to an embodiment, since the partition wall PW is provided to be flat, the lifting phenomenon of the tip portion TP in the partition wall PW may be prevented, and through this, it is possible to provide the display panel DP with improved process reliability and an improved degree of design freedom. Hereinafter, this will be described in detail with reference to FIGS. 6A and 6B illustrating comparative embodiments.

FIG. 6A illustrates a first comparative embodiment. As illustrated in FIG. 6A, according to the first comparative embodiment, a generally flat fifth insulating layer 50-A without forming a groove is provided so that an anode AE-A may be disposed on the flat upper surface of the fifth insulating layer 50-A. When the anode AE-A is disposed on the flat fifth insulating layer 50-A, in a pixel defining layer PDL-A, a step difference may be formed between a portion in which the anode AE-A is disposed and a portion in which the anode AE-A is not disposed, and accordingly, a step difference may be formed in each of a first layer L1-A and a second layer L2-A of a partition wall PW-A. In this case, each of first and second inner side surfaces S1-PA and S2-PA may face upward compared to other embodiments due to the step difference between the first and second layers L1-A and L2-A, and through this, the lifting phenomenon of a tip portion TP-A may occur. Accordingly, according to the first comparative embodiment, as illustrated in FIG. 6A, a light-emitting pattern EP-A may be deposited to generally cover the first inner side surface S1-PA, so that the cathode CE-A may not come in contact with the first inner side surface S1-PA. Alternatively, the cathode CE-A may not secure a sufficient contact area with the first inner side surface S1-PA. In this case, the cathode CE-A may not receive a bias voltage from the partition wall PW-A, and therefore, a defective pixel may be provided.

FIG. 6B illustrates a second comparative embodiment. As illustrated in FIG. 6B, according to the second comparative embodiment, a fifth insulating layer 50-B is provided which is generally flat without forming a groove like in the first comparative embodiment, and therefore, the anode AE-B may be disposed on the upper surface of the flat fifth insulating layer 50-B. In this case, in the second comparative embodiment, compared to the first comparative embodiment, a region (or margin region) of an anode AE-B, which overlaps a pixel defining layer PDL-B, is increased. Through this, as the lifting phenomenon of a tip portion TP-B may be prevented, it is possible not only to prevent a light-emitting pattern EP-B from being deposited to generally cover a first inner side surface S1-PB, but also for a cathode CE-B to secure a sufficient contact area with the first inner side surface S1-PB.

However, according to the second comparative embodiment, the ratio of an area of the anode AE-B exposed by the pixel defining layer PDL-B to the total area of the anode AE-B may be reduced. Assuming that the area of the anode AE-B is the same as that of the first comparative embodiment, the ratio of the area of the light-emitting opening OP-E (see FIG. 5A) to the area of the anode AE-B may be reduced, and display efficiency may be lowered due to the area reduction of the light-emitting region PXA (see FIG. 5A). Alternatively, in order to secure the same area of the light-emitting opening OP-E (see FIG. 5A) as in the first comparative embodiment, the total area of the anode (AE-B) should be increased, and accordingly, the degree of design freedom may be reduced due to space limitation.

On the other hand, according to an embodiment, as illustrated in FIGS. 5A and 5B, as the anode AE, the sacrificial pattern SP, and the fifth insulating layer 50 provide a flat surface, the pixel defining layer PDL and the partition wall PW may be formed to be flat, and the lifting phenomenon of the tip portion TP in the partition wall PW may be prevented. Accordingly, it is possible not only to prevent the formation of a defective light-emitting element ED, in which electrical connection with the partition wall PW is blocked, but also to provide the display panel DP having improved process reliability.

In addition, according to an embodiment, the lifting phenomenon of the tip portion TP may be prevented although a region (or margin region) of the anode AE overlapping the pixel defining layer PDL is not secured to a certain level or higher. That is, although the total area of the anode AE is not increased, the lifting phenomenon of the tip portion TP may be prevented, and therefore, it is possible to provide the display panel DP with an improved degree of design freedom.

In addition, according to an embodiment, a wider light-emitting region PXA may be secured compared to the second comparative embodiment, and therefore, it is possible to provide the display panel DP with improved display efficiency. For example, in order to prevent the lifting phenomenon of the tip portion TP-B in the second comparative embodiment, the width of the margin region on a cross section should be provided to be about 1.4 times or more greater than that of this embodiment. Therefore, according to this embodiment, compared to the second comparative embodiment, the area of the light-emitting opening OP-E corresponding to the first light-emitting region PXA-R (see FIG. 4) may be increased by about 1.8 times or more, the area of the light-emitting opening OP-E corresponding to the second light-emitting region PXA-G (see FIG. 4) may be increased by about 2.1 times or more, and the area of the light-emitting opening OP-E corresponding to the third light-emitting region PXA-B (see FIG. 4) may be increased by about 1.5 times or more.

Meanwhile, although FIG. 5A exemplarily illustrates that the light-emitting pattern EP comes in contact with the first inner side surface S1-P of the first layer L1, the embodiment of the invention is not limited thereto, and the light-emitting pattern EP may not come in contact with the first inner side surface S1-P.

According to an embodiment of the invention, the display panel DP may further include a capping pattern CP. The capping pattern CP is disposed in the partition wall opening OP-P and may be disposed on the cathode CE. The capping pattern CP may be patterned by the tip portion formed in the partition wall PW. The capping pattern CP may include at least any one of an inorganic layer or an organic layer. The capping pattern CP may protect the light-emitting element ED disposed thereunder.

In an embodiment, the dummy patterns DMP may be disposed on the partition wall PW. The dummy patterns DMP may include a first dummy pattern D1, a second dummy pattern D2, and a third dummy pattern D3. The first to third dummy patterns D1, D2, and D3 may be sequentially stacked along the third direction DR3 on the upper surface of the second layer L2 of the partition wall PW.

In an embodiment, the first dummy pattern D1 may contain an organic material. For example, the first dummy pattern D1 may contain the same material as the light-emitting pattern EP. The first dummy pattern D1 may be simultaneously formed with the light-emitting pattern EP through one process and formed separately from the light-emitting pattern EP by the undercut shape of the partition wall PW.

In an embodiment, the second dummy pattern D2 may contain a conductive material. For example, the second dummy pattern D2 may contain the same material as the cathode CE. The second dummy pattern D2 may be simultaneously formed with the cathode CE through one process and formed separately from the cathode CE by the undercut shape of the partition wall PW.

In an embodiment, the third dummy pattern D3 may include at least any one of an inorganic layer or an organic layer. The third dummy pattern D3 may contain the same material as the capping pattern CP. The third dummy pattern D3 may be simultaneously formed with the capping pattern CP through one process and formed separately from the capping pattern CP by the undercut shape of the partition wall PW.

In an embodiment, a dummy opening OP-D may be defined in the dummy patterns DMP. The dummy opening OP-D may correspond to the light-emitting opening OP-E. The dummy opening OP-D may be defined by the inner side surfaces of the first dummy pattern D1, the second dummy pattern D2, and the third dummy pattern D3. In an embodiment of the invention, the inner side surfaces of the first to third dummy patterns may be substantially aligned with each other and may form an integral opening space of the dummy opening OP-D. On a plane, each of the first dummy pattern D1, the second dummy pattern D2, and the third dummy pattern D3 may have a closed-line shape surrounding a corresponding light-emitting region PXA.

In an embodiment, FIG. 5A exemplarily illustrates that the inner side surfaces of the first dummy pattern D1, the second dummy pattern D2, and the third dummy pattern D3 are aligned with the second inner side surface S2-P of the second layer L2, but the embodiment of the invention is not limited thereto, and the first dummy pattern D1, the second dummy pattern D2, and the third dummy pattern D3 may cover at least a portion of the second inner side surface S2-P of the second layer L2.

In an embodiment, the thin layer encapsulation layer TFE may be disposed on the display element layer D-OL. The thin layer encapsulation layer TFE may include a lower encapsulation inorganic pattern LIL, an encapsulation organic layer OL, and an upper encapsulation inorganic layer UIL.

In an embodiment, the lower encapsulation inorganic pattern LIL may be disposed to correspond to the light-emitting opening OP-E. The lower encapsulation inorganic pattern LIL may cover the light-emitting element ED and the dummy patterns DMP, and a portion of the lower encapsulation inorganic pattern LIL may be disposed inside the partition wall opening OP-P.

In an embodiment, the encapsulation organic layer OL may cover the lower encapsulation inorganic pattern LIL and provide a flat upper surface. The upper encapsulation inorganic layer UIL may be disposed on the encapsulation organic layer OL.

In an embodiment, the lower encapsulation inorganic pattern LIL and the upper encapsulation inorganic layer UIL may protect the display element layer D-OL from moisture/oxygen, and the encapsulation organic layer OL may protect the display element layer D-OL from foreign substances such as dust particles.

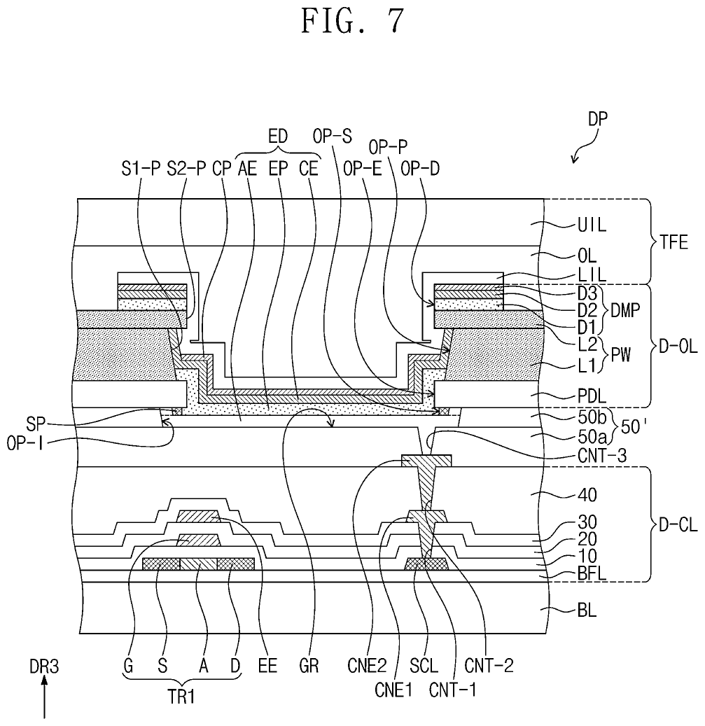

FIG. 7 is an enlarged cross-sectional view of a partial region of the display panel according to an embodiment of the invention. Same/similar reference numerals will be used for the same/similar elements as those described in FIGS. 5A to 6B, and redundant descriptions will be omitted.

Referring to FIG. 7, in the display panel DP according to an embodiment of the invention, a fifth insulating layer 50′ may be formed of a plurality of films. In an embodiment, the fifth insulating layer 50′ may include a lower film 50a and an upper film 50b. The lower film 50a may be provided to be generally flat, and the upper film 50b may be disposed on the lower film 50a and include an opening OP-I (or insulating opening) defined therein to partially pass therethrough. In an embodiment, the opening OP-I of the upper film 50b may provide a space in which the anode AE and the sacrificial pattern SP may be disposed, and the anode AE may be disposed on the upper surface of the lower film 50a exposed by the opening OP-I. The opening OP-I of the upper film 50b and the upper surface of the lower film 50a exposed through the opening OP-I may define the groove GR of the fifth insulating layer 50′.

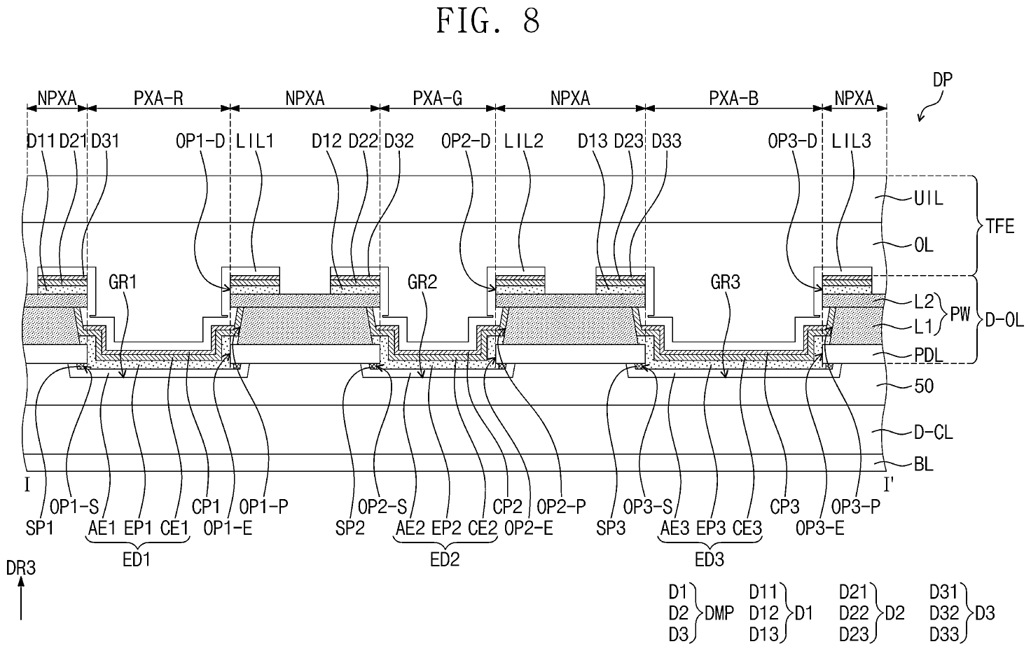

FIG. 8 is a cross-sectional view of the display panel according to an embodiment of the invention, which is taken along line I-I′ of FIG. 4. In an embodiment, FIG. 8 is an enlarged view of one first light-emitting region PXA-R, one second light-emitting region PXA-G, and one third light-emitting region PXA-B, and the description of one light-emitting region PXA of FIGS. 5A and 5B may be equally applied to each of the first light-emitting region PXA-R, the second light-emitting region PXA-G, and the third light-emitting region PXA-B.

Referring to FIG. 8, the display panel DP according to an embodiment may include a base layer BL, a circuit element layer D-CL, a fifth insulating layer 50, a display element layer D-OL, and an encapsulation layer TFE. The display element layer D-OL may include light-emitting elements ED1, ED2, and ED3, sacrificial patterns SP1, SP2, and SP3, a pixel defining layer PDL, a partition wall PW, and dummy patterns DMP.

In an embodiment, the light-emitting elements ED1, ED2, and ED3 may include a first light-emitting element ED1, a second light-emitting element ED2, and a third light-emitting element ED3.

In an embodiment, the first light-emitting element ED1 may include a first anode AE1 (or (1-1)-th electrode), a first light-emitting pattern EP1, and a first cathode CE1 (or (2-1)-th electrode), the second light-emitting element ED2 may include a second anode AE2 (or (1-2)-th electrode), a second light-emitting pattern EP2, and a second cathode CE2 (or (2-2)-th electrode), and the third light-emitting element ED3 may include a third anode AE3 (or (1-3)-th electrode), a third light-emitting pattern EP3, and a third cathode CE3 (or (2-3)-th electrode). The first anode AE1, the second anode AE2, and the third anode AE3 may be provided as a plurality of patterns. In an embodiment of the invention, the first light-emitting pattern EP1 may provide red light, the second light-emitting pattern EP2 may provide green light, and the third light-emitting pattern EP3 may provide blue light.

In an embodiment, a first light-emitting opening OP1-E, a second light-emitting opening OP2-E, and a third light-emitting opening OP3-E, may be defined in the pixel defining layer PDL.

In an embodiment, the first light-emitting opening OP1-E may expose at least a portion of the first anode AE1. The first light-emitting region PXA-R may be defined as a region exposed through the first light-emitting opening OP1-E among the upper surface of the first anode AE1. The second light-emitting opening OP2-E may expose at least a portion of the second anode AE2. The second light-emitting region PXA-G may be defined as a region exposed through the second light-emitting opening OP2-E among the upper surface of the second anode AE2. The third light-emitting opening OP3-E may expose at least a portion of the third anode AE3. The third light-emitting region PXA-B may be defined as a region exposed through the third light-emitting opening OP3-E among the upper surface of the third anode AE3.

In an embodiment, the sacrificial patterns SP1, SP2, and SP3 may include a first sacrificial pattern SP1, a second sacrificial pattern SP2, and a third sacrificial pattern SP3. The first sacrificial pattern SP1, the second sacrificial pattern SP2, and the third sacrificial pattern SP3 may be respectively disposed on the upper surfaces of the first anode AE1, the second anode AE2, and the third anode AE3. A first sacrificial opening OP1-S, a second sacrificial opening OP2-S, a third sacrificial opening OP3-S corresponding to the first to third light-emitting openings OP1-E, OP2-E, and OP3-E, respectively may be defined in the sacrificial patterns SP1, SP2, and SP3.

In an embodiment, a first partition wall opening OP1-P, a second partition wall opening OP2-P, and a third partition wall opening OP3-P corresponding to the first to third light-emitting openings OP1-E, OP2-E, and OP3-E, respectively may be defined in the partition wall PW. Each of the first partition wall opening OP1-P, the second partition wall opening OP2-P, and the third partition wall opening OP3-P may include a first region A1 (see FIG. 10B) and a second region A2 (see FIG. 10B).

In an embodiment, the first layer L1 may include the first inner side surfaces S1-P (see FIG. 5A) defining the first regions A1 (see FIG. 10B) of the first partition wall opening OP1-P, the second partition wall opening OP2-P, and the third partition wall opening OP3-P and the second layer L2 may include the second inner side surfaces S2-P (see FIG. 5A) defining the second regions A2 (see FIG. 10B) of the first partition wall opening OP1-P, the second partition wall opening OP2-P, and the third partition wall opening OP3-P.

In an embodiment, the first light-emitting pattern EP1 and the first cathode CE1 may be disposed in the first partition wall opening OP1-P, the second light-emitting pattern EP2 and the second electrode CE2 may be disposed in the second partition wall opening OP2-P, and the third light-emitting pattern EP3 and the third cathode CE3 may be disposed in the third partition wall opening OP3-P. The first cathode CE1, the second cathode CE2, and the third cathode CE3 may respectively come in contact with the first inner side surfaces S1-P of the first layer L1 (see FIG. 5A).

In an embodiment, the first cathode CE1, the second cathode CE2, and the third cathode CE3 may be physically separated by the second layer L2 configured to form a tip portion and may be respectively formed in the light-emitting openings OP1-E, OP2-E, and OP3-E. The first cathode CE1, the second cathode CE2, and the third cathode CE3 come in contact with the first layer L1 so that they may be electrically connected to each other and receive a common voltage. As the first layer L1 has a relatively higher electrical conductivity and a larger thickness than the second layer L2, contact resistance to the first cathode CE1, the second cathode CE2, and the third cathode CE3 may be reduced. Accordingly, a common cathode voltage may be uniformly provided to the light-emitting regions PXA-R, PXA-G, and PXA-B.

According to an embodiment, the plurality of first light-emitting patterns EP1 may be patterned and deposited in pixel units by the tip portion defined in the partition wall PW. That is, the first light-emitting patterns EP1 are commonly formed by using an open mask, but may be easily divided into the pixel units by the partition wall PW.

In an embodiment, on the other hand, when the first light-emitting patterns EP1 are patterned by using a fine metal mask (FMM), a support spacer protruding from the partition wall should be provided to support the fine metal mask. In addition, since the fine metal mask is spaced apart from the base surface, on which patterning is performed, by the height of the partition wall and the spacer, there may be a limitation in implementing high resolution. In addition, as the fine metal mask comes in contact with the spacer, foreign substances may remain on the spacer after the patterning process of the first light-emitting patterns EP1, or the spacer may be damaged by being nicked by the fine metal mask. Accordingly, a defective display panel may be formed. The description of this may be equally applied to a case in which the second light-emitting patterns EP2 are patterned and a case in which the third light-emitting patterns EP3 are patterned.

According to an embodiment, physical separation between the light-emitting elements ED1, ED2, and ED3 may be easily achieved by including the partition wall PW. Accordingly, a current leakage and/or a driving error between adjacent light-emitting regions PXA-R, PXA-G, and PXA-B may be prevented, and it is possible to drive each of the light-emitting elements ED1, ED2, and ED3 independently.

In particular, in an embodiment, by patterning the plurality of first light-emitting patterns EP1 without a mask in contact with internal components in the display region DA (see FIG. 2), the defect rate may be reduced, thus making it possible to provide the display panel DP with improved process reliability. This may be equally applied to the case in which the second light-emitting patterns EP2 are patterned and the case in which the third light-emitting patterns EP3 are patterned. Since patterning is possible even when a separate support spacer protruding from the partition wall PW is not provided, the areas of the light-emitting regions PXA-R, PXA-G, and PXA-B may be minimized and therefore, it is possible to provide the display panel DP that easily implements a high resolution.

In addition, in an embodiment, in manufacturing a large-area display panel DP, process costs may be reduced by omitting the manufacture of a large-area mask, and by being not affected by a defect which may occur in the large-area mask, it is possible to provide the display panel DP with improved process reliability.

In an embodiment, the capping patterns CP1, CP2, and CP3 may include a first capping pattern CP1, a second capping pattern CP2, and a third capping pattern CP3. The first capping pattern CP1, the second capping pattern CP2, and the third capping pattern CP3 may be respectively disposed on the first cathode CE1, the second cathode CE2, and the third cathode CE3 in the first partition wall opening OP1-P, the second partition wall opening OP2-P, and the third partition wall opening OP3-P.

In an embodiment, the dummy patterns DMP may include a plurality of first dummy patterns D1, a plurality of second dummy patterns D2, and a plurality of third dummy patterns D3.

In an embodiment, the first dummy patterns D1 may include a (1-1)-th dummy pattern D11, a (1-2)-th dummy pattern D12, and a (1-3)-th dummy pattern D13 which respectively surround the first light-emitting region PXA-R, the second light-emitting region PXA-G, and the third light-emitting region PXA-B on a plane. The (1-1)-th dummy pattern D11, the (1-2)-th dummy pattern D12, and the (1-3)-th dummy pattern D13 may contain the same material as the first light-emitting pattern EP1, the second light-emitting pattern EP2, and the third light-emitting pattern EP3, respectively and may be formed in the same process as that of the first light-emitting pattern EP1, the second light-emitting pattern EP2, and the third light-emitting pattern EP3, respectively.

In an embodiment, the second dummy patterns D2 may include a (2-1)-th dummy pattern D21, a (2-2)-th dummy pattern D22, and a (2-3)-th dummy pattern D23 which respectively surround the first light-emitting region PXA-R, the second light-emitting region PXA-G, and the third light-emitting region PXA-B on a plane. The (2-1)-th dummy pattern D21, the (2-2)-th dummy pattern D22, and the (2-3)-th dummy pattern D23 may contain the same material as the first cathode CE1, the second cathode CE2, and the third cathode CE3, respectively, and may be formed in the same process as that of the first cathode CE1, the second cathode CE2, and the third cathode CE3, respectively.

In an embodiment, the third dummy patterns D3 may include a (3-1)-th dummy pattern D31, a (3-2)-th dummy pattern D32, and a (3-3)-th dummy pattern D33 which respectively surround the first light-emitting region PXA-R, the second light-emitting region PXA-G, and the third light-emitting region PXA-B on a plane. The (3-1)-th dummy pattern D31, the (3-2)-th dummy pattern D32, and the (3-3)-th dummy pattern D33 may contain the same material as the first capping pattern CP1, the second capping pattern CP2, and the third capping pattern CP3, respectively, and may be formed in the same process as that of the first capping pattern CP1, the second capping pattern CP2, and the third capping pattern CP3, respectively.

In an embodiment, in the dummy patterns DMP, a first dummy opening OP1-D, a second dummy opening OP2-D, and a third dummy opening OP3-D corresponding to the first light-emitting opening OP1-E, the second light-emitting opening OP2-E, and the third light-emitting opening OP3-E, respectively, may be defined. The first dummy opening OP1-D may be defined by the inner side surfaces of the (1-1)-th dummy pattern D11, the (2-1)-th dummy pattern D21, and the (3-1)-th dummy pattern D31, the second dummy opening OP2-D may be defined by the inner side surfaces of the (1-2)-th dummy pattern D12, the (2-2)-th dummy pattern D22, and the (3-2)-th dummy pattern D32, and the third dummy opening OP3-D may be defined by the inner side surfaces of the (1-3)-th dummy pattern D13, the (2-3)-th dummy pattern D23, and the (3-3)-th dummy pattern D33.

In an embodiment, the thin film encapsulation layer TFE may include lower encapsulation inorganic patterns LIL1, LIL2, and LIL3, an encapsulation organic film OL, and an upper encapsulation inorganic film UIL. In an embodiment, the lower encapsulation inorganic patterns LIL1, LIL2, and LIL3 may include a first lower encapsulation inorganic pattern LIL1, a second lower encapsulation inorganic pattern LIL2, and a third lower encapsulation inorganic pattern LIL3. The first lower encapsulation inorganic pattern LIL1, the second lower encapsulation inorganic pattern LIL2, and the third lower encapsulation inorganic pattern LIL3 may be disposed to respectively correspond to the first light-emitting opening OP1-E, the second light-emitting opening OP2-E, and the third light-emitting opening OP3-E.

In an embodiment, the first lower encapsulation inorganic pattern LIL1 may cover the first light-emitting element ED1 and the (1-1)-th dummy pattern D11, the (2-1)-th dummy pattern D21, and the (3-1)-th dummy pattern D31 and may be partially disposed inside the first partition wall opening OP1-P. The second lower encapsulation inorganic pattern LIL2 may cover the second light-emitting element ED2 and the (1-2)-th dummy pattern D12, the (2-2)-th dummy pattern D22, and the (3-2)-th dummy pattern D32 and may be partially disposed inside the second partition wall opening OP2-P. The third lower encapsulation inorganic pattern LIL3 may cover the third light-emitting element ED3 and the (1-3)-th dummy pattern D13, the (2-3)-th dummy pattern D23, and the (3-3)-th dummy pattern D33, and may be partially disposed inside the third partition wall opening OP3-P. The first lower encapsulation inorganic pattern LIL1, the second lower encapsulation inorganic pattern LIL2, and the third lower encapsulation inorganic pattern LIL3 may be provided in a form of patterns spaced apart from each other.

In an embodiment, the upper surface Ua (see FIG. 5B) of each of the first anode AE1, the second anode AE2, and the third anode AE3 covered by the pixel defining layer PDL, the upper surface Us (see FIG. 5B) of each of the first sacrificial pattern SP1, the second sacrificial pattern SP2, and the third sacrificial pattern SP3 and the upper surface Ui (see FIG. 5B) of the fifth insulating layer 50 may be substantially coplanar with each other and, through this, all of the pixel defining layer PDL and the partition wall PW disposed on the fifth insulating layer 50 may be provided to be flat. That is, no step difference may be formed in each of the pixel defining layer PDL and the partition wall PW, and therefore, it is possible to provide the display panel DP with improved process reliability, display efficiency, and degree of design freedom.

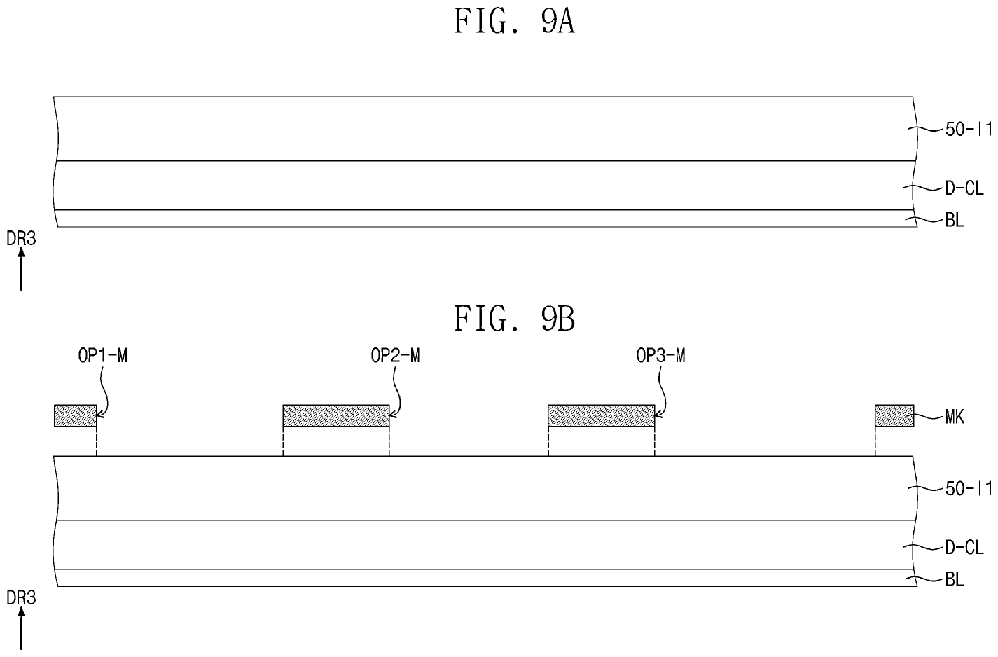

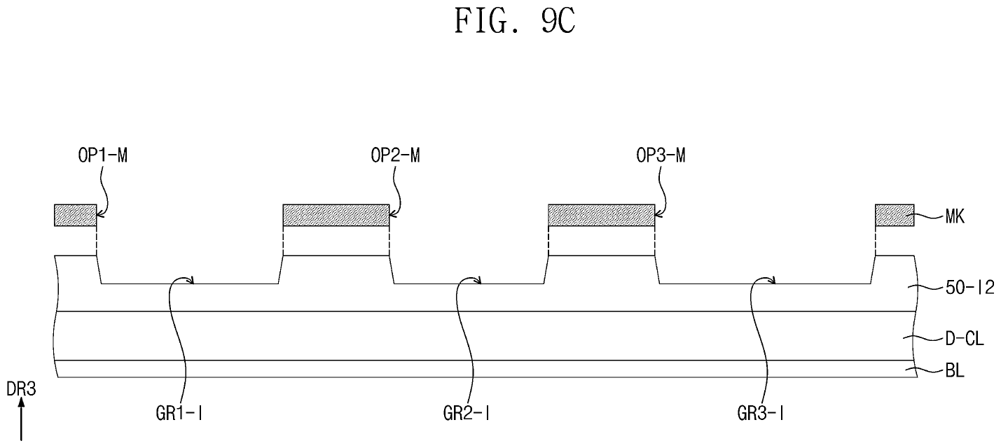

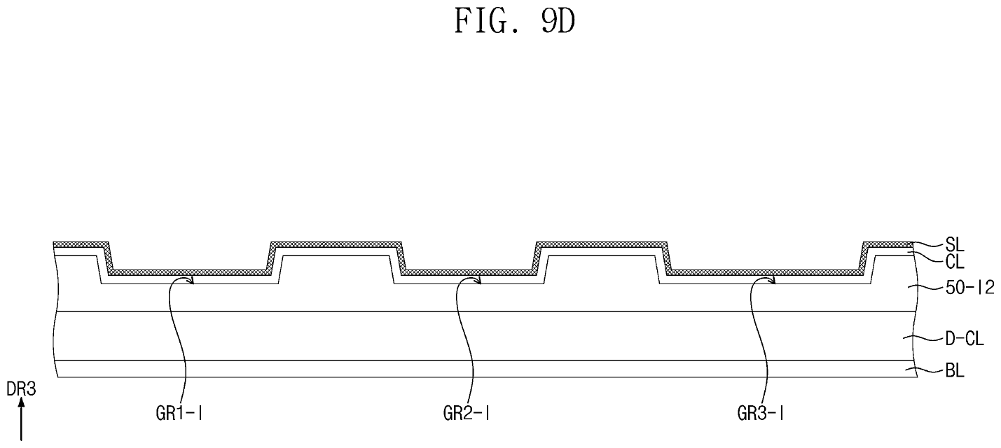

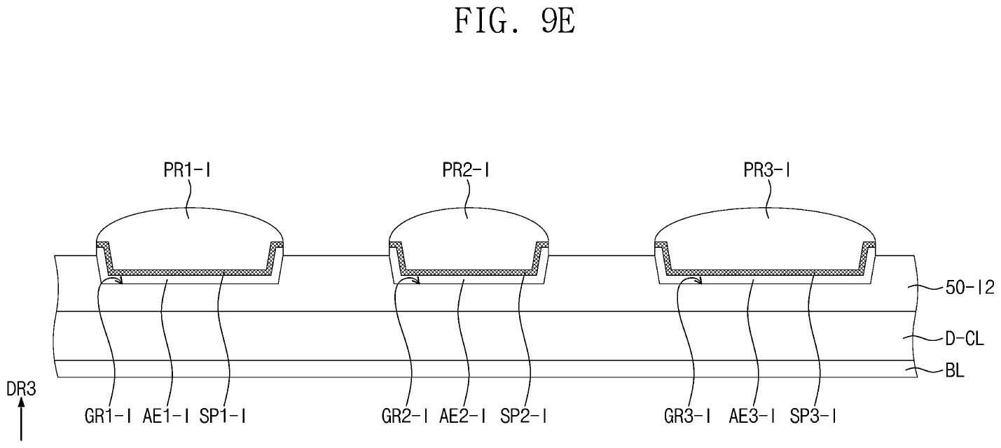

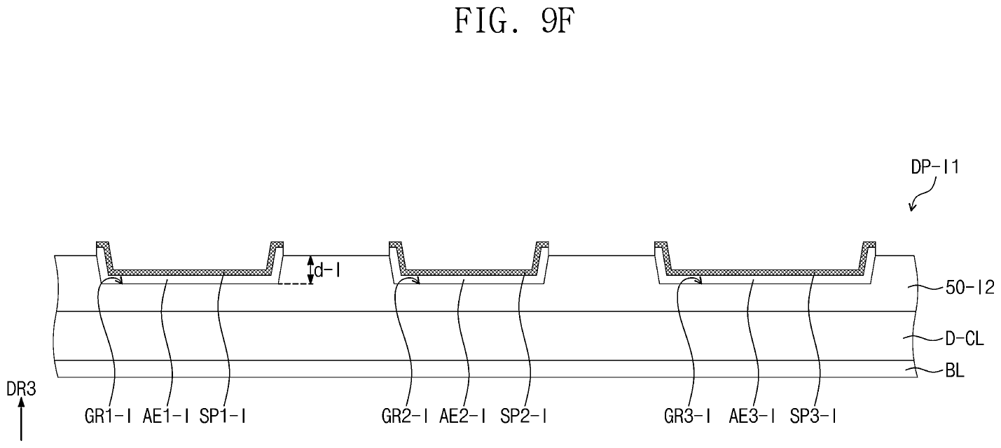

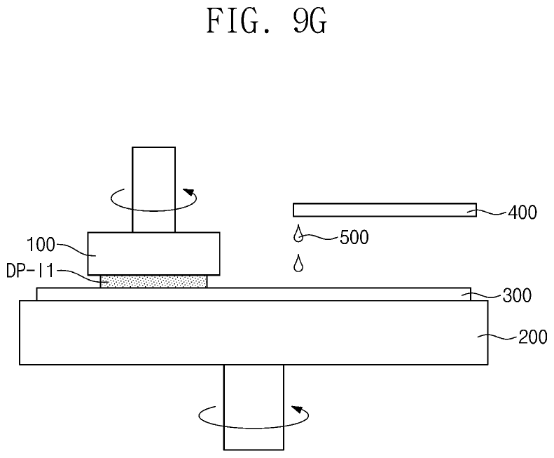

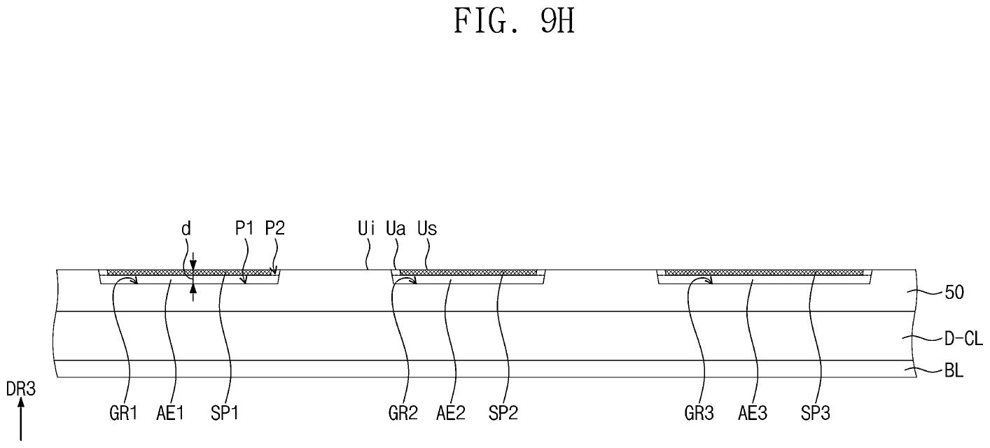

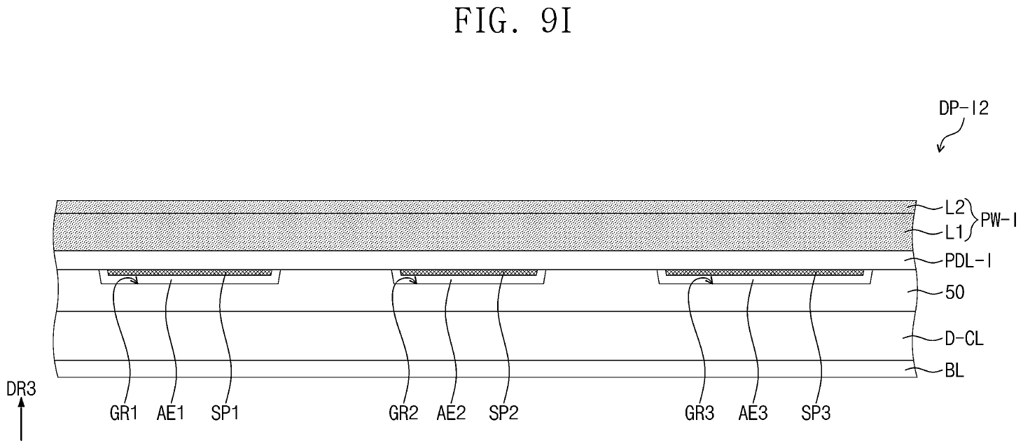

In an embodiment, FIGS. 9A to 9H illustrate steps of forming a first preliminary display panel and then forming a second preliminary display panel, and in an embodiment, FIGS. 10A to 10K illustrate steps of forming a display panel including first to third light-emitting elements from the second preliminary display panel.

In an embodiment, a method of manufacturing a display panel may include forming an anode disposed in a groove defined in an insulating layer, forming a partition wall disposed on the insulating layer and having a partition wall opening defined therein and overlapping the anode, forming a pixel defining layer disposed between the insulating layer and the partition wall and having a light-emitting opening defined therein and corresponding to the partition wall opening, forming a light-emitting pattern at least partially disposed in the light-emitting opening and forming a cathode at least partially disposed in the partition wall opening and coming in contact with an inner side surface of the partition wall defining the partition wall opening, wherein an upper surface of the anode covered by the pixel defining layer may be substantially coplanar with an upper surface of the insulating layer.

In an embodiment, the method of manufacturing the display panel may include a first group process, a second group process, a third group process, a fourth group process, and a fifth group process. The first group process (or pre-processing process) may be a process of preparing a preliminary display panel DP-I2 (see FIG. 9i) in which a preliminary partition wall PW-I (see FIG. 9i) is formed, the second to fourth group processes may be processes of respectively forming the first light-emitting element ED1, the second light-emitting element ED2, and the third light-emitting element ED3 (see FIG. 10K), and the fifth group process (or post-processing process) may be a process of completing the display panel DP (see FIG. 10L) by forming the remaining components of the encapsulation layer TFE (see FIG. 10L).

In an embodiment, first, the first group process will be described with reference to FIGS. 9A to 9I.

Referring to FIG. 9A, the first group process according to an embodiment may include forming a first preliminary insulating layer 50-I1 on the base substrate.

In an embodiment, the base substrate may include a base layer BL and a circuit element layer D-CL disposed on the base layer BL. The circuit element layer D-CL may be formed through a typical circuit element manufacturing process in which an insulating layer, a semiconductor layer, and a conductive layer are formed by a method such as coating or deposition, and then a semiconductor pattern, a conductive pattern, a signal line, and the like are formed by selectively patterning the insulating layer, the semiconductor layer, and/or the conductive layer through photolithography and etching processes.

In an embodiment, the first preliminary insulating layer 50-I1 may be deposited and formed on an insulating layer (e.g., the fourth insulating layer 40 of FIG. 5A) disposed at the uppermost side of the circuit element layer D-CL.

Referring to FIGS. 9B and 9C, the first group process according to an embodiment may include patterning the first preliminary insulating layer 50-I1 so that a second preliminary insulating layer 50-I2 is formed from the first preliminary insulating layer 50-I1. In an embodiment, the second preliminary insulating layer 50-I2 may be formed through an exposure process and a developing process of the first preliminary insulating layer 50-I1.

In an embodiment, first, by disposing a mask MK on the first preliminary insulating layer 50-I1 and providing light to the first preliminary insulating layer 50-I1, the exposure process of the first preliminary insulating layer 50-I1 may be performed. In an embodiment, a first mask opening OP1-M, a second mask opening OP2-M, and a third mask opening OP3-M may be defined in the mask MK. Out of light passing through the mask openings OP1-M, OP2-M, and OP3-M among the provided light, a first amount of light per unit area may be provided to a portion of the first preliminary insulating layer 50-I1 overlapping the mask openings OP1-M, OP2-M, and OP3-M.

In an embodiment, the mask MK may transmit some of the provided light. For example, the mask MK may be composed of a filter. Out of light passing through the mask MK among the provided light, a second amount of light per unit area may be provided to a portion of the first preliminary insulating layer 50-I1 overlapping the mask MK, and the second amount of light may be less than the first amount of light.

In an embodiment, hereafter, a portion of the first preliminary insulating layer 50-I1 may be removed through a developing process of the first preliminary insulating layer 50-I1 exposed to light. In an embodiment, as a portion overlapping the mask openings OP1-M, OP2-M, and OP3-M is exposed to a greater amount of light than a portion overlapping the mask MK, the portion overlapping the mask openings OP1-M, OP2-M, and OP3-M may be removed more than the portion overlapping the mask MK. Through this, the second preliminary insulating layer 50-I2 may be formed in which a first initial groove GR1-I corresponding to the first mask opening OP1-M, a second initial groove GR2-I corresponding to the second mask opening OP2-M, and a third initial groove GR3-I corresponding to the third mask opening OP3-M are defined.

Referring to FIG. 9D, the first group process according to an embodiment may include forming a conductive layer CL on the second preliminary insulating layer 50-I2 and forming a sacrificial layer SL on the conductive layer CL. Each of the conductive layer CL and the sacrificial layer SL may be formed by depositing a conductive material. For example, each of the conductive layer CL and the sacrificial layer SL may be formed through a sputtering process.

Referring to FIGS. 9D and 9E, the first group process according to an embodiment may include patterning each of the conductive layer CL and the sacrificial layer SL.

In an embodiment, first, a first initial photoresist layer PR1-I, a second initial photoresist layer PR2-I, and a third initial photoresist layer PR3-I overlapping the first initial groove GR1-I, the second initial groove GR2-I, and the third initial groove GR3-I, respectively, may be formed on the sacrificial layer SL. Hereafter, by using the first initial photoresist layer PR1-I, the second initial photoresist layer PR2-I, and the third initial photoresist layer PR3-I as masks and wet-etching the sacrificial layer SL and the conductive layer CL, a first preliminary sacrificial pattern SP1-I, a second preliminary sacrificial pattern SP2-I, and a third preliminary sacrificial pattern SP3-I may be formed from the sacrificial layer SL, and a first preliminary anode AE1-I, a second preliminary anode AE2-I, and a third preliminary anode AE3-I may be formed from the conductive layer CL.

Referring to FIG. 9F, the first group process according to an embodiment may include removing the first initial photoresist layer PR1-I, the second initial photoresist layer PR2-I, and the third initial photoresist layer PR3-I (see FIG. 9E). In an embodiment, after removing the first initial photoresist layer PR1-I, the second initial photoresist layer PR2-I, and the third initial photoresist layer PR3-I (see FIG. 9E), the remaining base layer BL, circuit element layer D-CL, second preliminary insulating layer 50-I2, a first preliminary anode AE1-I, a second preliminary anode AE2-I, and a third preliminary anode AE3-I, and a first preliminary sacrificial pattern SP1-I, a second preliminary sacrificial pattern SP2-I, and a third preliminary sacrificial pattern SP3-I are referred to as a “first preliminary display panel DP-I1”.

Referring to FIGS. 9F to 9H, the first group process according to an embodiment may include planarizing the first preliminary display panel DP-I1. In an embodiment, planarization of the first preliminary display panel DP-I1 may be performed through a chemical mechanical polishing (CMP) process. The CMP process is a process of planarizing the upper portion of a substrate by chemically and mechanically polishing the substrate on which a step difference is formed.

In an embodiment, FIG. 9G is a cross-sectional view schematically illustrating a process of planarizing the first preliminary display panel DP-I1 through a CMP process. Referring to FIG. 9G, the first preliminary display panel DP-I1 may be coupled to a carrier 100 and rotated by the carrier 100. In this case, the first preliminary display panel DP-I1 may rotate in a state in which the first preliminary display panel DP-I1 is in contact with a polishing pad 300 coupled to and rotated by a rotation plate 200 and therefore, the surface of the first preliminary display panel DP-I1 may be mechanically polished.

In addition, in an embodiment, by providing slurry 500 containing abrasive to the surface of the polishing pad 300 through a slurry supply nozzle 400, it is possible to make a chemical reaction occur together on the surface of the first preliminary display panel DP-I1. Through this, by removing protruding portions of the first preliminary display panel DP-I1, which protrude due to a step difference, the step difference of the first preliminary display panel DP-I1 is removed and therefore, the first preliminary display panel DP-I1 may have a flat upper surface.

In an embodiment, referring to FIGS. 9F and 9H, through a planarization process of the first preliminary display panel DP-I1, a portion of the second preliminary insulating layer 50-I2, a portion of each of the first preliminary anode AE1-I, the second preliminary anode AE2-I, and the third preliminary anode AE3-I and a portion of each of the first preliminary sacrificial pattern SP1-I, the second preliminary sacrificial pattern SP2-I, and the third preliminary sacrificial pattern SP3-I may be removed. Accordingly, an insulating layer 50 in which a first groove GR1, a second groove GR2, and a third groove GR3 are defined may be formed from the second preliminary insulating layer 50-I2. The insulating layer 50 of FIG. 9H may correspond to the fifth insulating layer 50 described above with reference to FIG. 5A. A depth d of the first groove GR1, the second groove GR2, and the third groove GR3 may be smaller than a depth d−I of the first initial groove GR1-I, the second initial groove GR2-I, and the third initial groove GR3-I, respectively. In addition, the first anode AE1, the second anode AE2, and the third anode AE3 may be respectively formed from the first preliminary anode AE1-I, the second preliminary anode AE2-I, and the third preliminary anode AE3-I, and the first sacrificial pattern SP1, the second sacrificial pattern SP2, and the third sacrificial pattern SP3 may be respectively formed from the first preliminary sacrificial pattern SP1-I, the second preliminary sacrificial pattern SP2-I, and the third preliminary sacrificial pattern SP3-I.

In an embodiment, each of the first anode AE1, the second anode AE2, and the third anode AE3 may be formed to include a first portion P1 and a second portion P2 extending in a direction away from the base layer BL from the first portion P1. The first portion P1 may come in contact with a portion forming a plane defined by the first direction DR1 and the second direction DR2 (see FIG. 1A) among a surface defining a corresponding groove.

In an embodiment, each of the first sacrificial pattern SP1, the second sacrificial pattern SP2, and the third sacrificial pattern SP3 may be disposed on the first portion P1 of a corresponding anode among the first anode AE1, the second anode AE2, and the third anode AE3, respectively, and may be surrounded by the second portion P2.

According to an embodiment, through a planarization process, the depth d of the first groove GR1 may be substantially equal to the maximum value of the sum of the thickness t1 (see FIG. 5B) of the first portion P1 of the first anode AE1 and the thickness t2 (see FIG. 5B) of the second portion P2 thereof. Through a planarization process, the depth of the second groove GR2 may be substantially equal to the maximum value of the sum of the thickness t1 (see FIG. 5B) of the first portion P1 of the second anode AE2 and the thickness t2 (see FIG. 5B) of the second portion P2 thereof. Through a planarization process, the depth of the third groove GR3 may be substantially equal to the maximum value of the sum of the thickness t1 (see FIG. 5B) of the first portion P1 of the third anode AE3 and the thickness t2 (see FIG. 5B) of the second portion P2 thereof. Alternatively, the depth d of the first groove GR1 may be substantially equal to the sum of the thickness t1 (see FIG. 5B) of the first portion P1 of the first anode AE1 and the thickness of the first sacrificial pattern SP1. The depth of the second groove GR2 may be substantially equal to the sum of the thickness t1 (see FIG. 5B) of the first portion P1 of the second anode AE2 and the thickness of the second sacrificial pattern SP2. The depth of the third groove GR3 may be substantially equal to the sum of the thickness t1 (see FIG. 5B) of the first portion P1 of the third anode AE3 and the thickness of the third sacrificial pattern SP3.

In an embodiment, specifically, by removing a portion of the second preliminary insulating layer 50-I2 protruding in a direction away from the base layer BL, the first groove GR1, the second groove GR2, and the third groove GR3 having a depth smaller than the depth of the first initial groove GR1-I, the second initial groove GR2-I, and the third initial groove GR3-I may be formed. In addition, by partially removing a portion of the first preliminary anode AE1-I, the second preliminary anode AE2-I, and the third preliminary anode AE3-I extending in a direction away from the base layer BL and at least partially removing a portion of the first preliminary sacrificial pattern SP1-I, the second preliminary sacrificial pattern SP2-I, and the third preliminary sacrificial pattern SP3-I extending in a direction away from the base layer BL, the upper surface Ua of the second portion P2 of each of the first anode AE1, the second anode AE2, and the third anode AE3, the upper surface Us of each of the first sacrificial pattern SP1, the second sacrificial pattern SP2, and the third sacrificial pattern SP3, and the upper surface Ui of the insulating layer 50 may become substantially coplanar with each other. That is, the anodes AE1, AE2, and AE3, the sacrificial patterns SP1, SP2, and SP3, and the insulating layer 50 may provide a flat surface.

Referring to FIG. 9I, the first group process according to an embodiment may include forming a preliminary pixel defining layer PDL-I on the insulating layer 50 and forming a preliminary partition wall PW-I on the preliminary pixel defining layer PDL-I.

In an embodiment, the preliminary pixel defining layer PDL-I may be disposed on the insulating layer 50 and cover the first sacrificial pattern SP1, the second sacrificial pattern SP2, and the third sacrificial pattern SP3, and the first anode AE1, the second anode AE2, and the third anode AE3. The preliminary pixel defining layer PDL-I may be formed by depositing an inorganic material. For example, the preliminary pixel defining layer PDL-I may be formed through a chemical vapor deposition process.

In an embodiment, as the preliminary pixel defining layer PDL-I is disposed on a flat surface provided by the anodes AE1, AE2, and AE3, the sacrificial patterns SP1, SP2, and SP3, and the insulating layer 50, the preliminary pixel defining layer PDL-I may also be provided to be flat. The preliminary pixel defining layer PDL-I may be formed to have substantially a same thickness and may not have a step difference.

In an embodiment, the preliminary partition wall PW-I may include a first layer L1 disposed on the preliminary pixel defining layer PDL-I and a second layer L2 disposed on the first layer L1. In an embodiment, the first layer L1 may contain a first conductive material having a first conductivity, and the second layer L2 may contain a second conductive material having a second conductivity, wherein the first conductivity may be higher than the second conductivity. The preliminary partition wall PW-I may be formed by sequentially depositing the first conductive material and the second conductive material. For example, the preliminary partition wall PW-I may be formed through a sputtering process.

In an embodiment, as the preliminary partition wall PW-I is disposed on the preliminary pixel defining layer PDL-I provided to be flat, both the first layer L1 and the second layer L2 may be provided to be flat. Each of the first layer L1 and the second layer L2 may be formed to have substantially a same thickness and may not have a step difference.

In an embodiment, the base layer BL, the circuit element layer D-CL, the insulating layer 50, the first anode AE1, the second anode AE2, and the third anode AE3, the first sacrificial pattern SP1, the second sacrificial pattern SP2, and the third sacrificial pattern SP3, the preliminary pixel defining layer PDL-I, and the preliminary partition wall PW-I are referred to as a “second preliminary display panel DP-I2”.

After the first group process, a second group process may be performed. In an embodiment, a first light-emitting element ED1 (see FIG. 10E) and a first lower encapsulation inorganic layer LIL1 (see FIG. 10E) covering the first light-emitting element ED1 (see FIG. 10E) may be formed through the second group process. Hereinafter, the second group process will be described with reference to FIGS. 10A to 10E.

Referring to FIG. 10A, the second group process according to an embodiment may include forming a first photoresist layer PR1 and forming a first preliminary partition wall opening OP1-PI in the preliminary partition wall PW-I through a first etching process.

In an embodiment, the first photoresist layer PR1 may be formed by forming a preliminary photoresist layer on the preliminary partition wall PW-I and then patterning the preliminary photoresist layer by using a photo mask. Through a patterning process, a first photo opening OP1-R overlapping the first groove GR1 may be formed in the first photoresist layer PR1.

In an embodiment, hereafter, in the first etching process, the first preliminary partition wall opening OP1-PI may be formed in the preliminary partition wall PW-I by dry-etching the first layer L1 and the second layer L2 with the use of the first photoresist layer PR1 as a mask. The dry etching of the first etching process may be performed in an etching environment in which the etching selectivity of the first layer L1 and the second layer L2 are substantially the same as each other. Accordingly, the inner side surface of the first layer L1 and the inner side surface of the second layer L2 defining the first preliminary partition wall opening OP1-PI may be substantially aligned with each other.

Hereafter, referring to FIG. 10B, the second group process according to an embodiment may include forming the first partition wall opening OP1-P from the first preliminary partition wall opening OP1-PI (See FIG. 10A) so that the partition wall PW is formed from the preliminary partition wall PW-I through a second etching process.

In an embodiment, in the second etching process, the first partition wall opening OP1-P including a first region A1 defined by the first inner side surface S1-P of the first layer L1 and a second region A2 defined by the second inner side surface S2-P of the second layer L2 may be formed by wet-etching the first layer L1 and the second layer L2 with the use of the first photoresist layer PR1 as a mask.

In an embodiment, the second etching process may be performed in an environment in which the etching selectivity between the first layer L1 and the second layer L2 is high. Accordingly, an inner side surface of the partition wall PW defining the first partition wall opening OP1-P may have an undercut shape on a cross section. Specifically, as the etch rate of the first layer L1 with respect to an etching solution is greater than the etch rate of the second layer L2, the first layer L1 may be mainly etched. Accordingly, the inner side surface of the first layer L1 may be formed to be recessed more inward than the inner side surface of the second layer L2. A tip portion may be formed in the partition wall PW by a portion of the second layer L2 protruding from the first layer L1.

Meanwhile, in an embodiment, depending on conditions of the second etching process, a second layer L2 may be partially etched together with a first layer L1, or the second layer L2 may not be etched.

Referring to FIG. 10C, the second group process according to an embodiment may include forming a pixel defining layer PDL, in which the first light-emitting opening OP1-E is defined, by patterning the preliminary pixel defining layer PDL-I (see FIG. 10B) through a third etching process. The third etching process may be performed by a dry etching method and may be performed by using the first photoresist layer PR1 and the partition wall PW (e.g., the second layer L2) as a mask.

The second group process according to an embodiment may include forming a first sacrificial opening OP1-S in the first sacrificial pattern SP1 so that at least a portion of the first anode AE1 is exposed through a fourth etching process. The fourth etching process may be performed by a wet etching method and may be performed by using the first photoresist layer PR1 and the pixel defining layer PDL, in which the first light-emitting opening OP1-E are defined, as a mask.

In an embodiment, the fourth etching process may be performed in an environment in which the etching selectivity between the first sacrificial pattern SP1 and the first anode AE1 is high, and through this, it is possible to prevent the first anode AE1 from being etched together. That is, by disposing the first sacrificial pattern SP1 having a higher etch rate than the first anode AE1 between the pixel defining layer PDL and the first anode AE1, it is possible to prevent the first anode AE1 from being etched together and damaged during an etching process.

Referring to FIG. 10D, the second group process according to an embodiment may include removing the first photoresist layer PR1 (see FIG. 10C). Hereafter, the second group process according to an embodiment may include forming a first light-emitting pattern EP1, forming a first cathode CE1, forming a first capping pattern CP1, and forming a first lower encapsulation inorganic layer LIL1-I.

In an embodiment, the forming of the first light-emitting pattern EP1 may be performed by depositing a first organic material. For example, the first light-emitting pattern EP1 may be formed through a thermal evaporation process, but the embodiment of the invention is not limited thereto. The forming of the first cathode CE1 may be performed by depositing a conductive material. For example, the first cathode CE1 may be formed through a sputtering process, but the embodiment of the invention is not limited thereto.

In an embodiment, the first light-emitting pattern EP1 may be separated by a tip portion formed in the partition wall PW and disposed in the first light-emitting opening OP1-E and the first partition wall opening OP1-P. The first cathode CE1 may be separated by a tip portion formed in the partition wall PW and disposed in the first partition wall opening OP1-P. The first cathode CE1 may be provided at a higher incidence angle than the first light-emitting pattern EP1 and formed to come in contact with the first inner side surface S1-P of the first layer L1 defining the first region A1 (see FIG. 10B) of the first partition wall opening OP1-P.

In an embodiment, the first capping pattern CP1 may be formed through a deposition process, and the first capping pattern CP1 may be separated by a tip portion formed in the partition wall PW and disposed in the first partition wall opening OP1-P.

In an embodiment, in the forming of the first light-emitting pattern EP1, a (1-1)-th dummy layer D11-I may be formed together on the partition wall PW. In the forming of the first cathode CE1, a (2-1)-th dummy layer D21-I may be formed together on the (1-1)-th dummy layer D11-I. In the forming of the first capping pattern CP1, a (3-1)-th dummy layer D31-I may be formed together on the (2-1)-th dummy layer D21-I.

In an embodiment, a first lower encapsulation inorganic layer LIL1-I may be formed through a chemical vapor deposition (CVD) process. The first lower encapsulation inorganic layer LIL1-I may be formed on the partition wall PW and the first cathode CE1, and a portion of the first lower encapsulation inorganic layer LIL1-I may be formed inside the first partition wall opening OP1-P.

Referring to FIGS. 10D and 10E, the second group process according to an embodiment may include forming a second photoresist layer PR2, patterning the first lower encapsulation inorganic layer LIL1-I through a fifth etching process, and patterning the (1-1)-th dummy layer D11-I through a sixth etching process.

In an embodiment, the second photoresist layer PR2 may be formed on the first lower encapsulation inorganic layer LIL1-I and may be formed in a pattern shape corresponding to the first light-emitting opening OP1-E.

In an embodiment, through the fifth etching process, a first lower encapsulation inorganic pattern LIL1 may be formed from the first lower encapsulation inorganic layer LIL1-I. In the fifth etching process, a portion of the first lower encapsulation inorganic layer LIL1-I overlapping the second anode AE2 and the third anode AE3 may be patterned to be removed by dry-etching the first lower encapsulation inorganic layer LIL1-I with the use of the second photoresist layer PR2 as a mask. The first lower encapsulation inorganic pattern LIL1 disposed to correspond to the first light-emitting opening OP1-E may be formed from the first lower encapsulation inorganic layer LIL1-I from which the portion is removed. A portion of the first lower encapsulation inorganic pattern LIL1 may be disposed in the first partition wall opening OP1-P to cover the first light-emitting element ED1, and another portion of the first lower encapsulation inorganic pattern LIL1 may be disposed on the partition wall PW.

In an embodiment, through the sixth etching process, a (1-1)-th dummy pattern D11 may be formed from the (1-1)-th dummy layer D11-I. In the sixth etching process, a portion of the (1-1)-th dummy layer D11-I overlapping the second anode AE2 and the third anode AE3 may be patterned to be removed by dry-etching the (1-1)-th dummy layer D11-I with the use of the second photoresist layer PR2 as a mask. The (1-1)-th dummy pattern D11 having a closed-line shape surrounding the first light-emitting region PXA-R (see FIG. 4) on a plane may be formed from the (1-1)-th dummy layer D11-I from which the portion is removed.

In an embodiment, in the sixth etching process, a portion of the (2-1)-th dummy layer D21-I overlapping the second anode AE2 and the third anode AE3 may be patterned to be removed by dry-etching the (2-1)-th dummy layer D21-I together. A (2-1)-th dummy pattern D21 having a closed-line shape surrounding the first light-emitting region PXA-R (see FIG. 4) on a plane may be formed from the (2-1)-th dummy layer D21-I from which the portion is removed. Meanwhile, the embodiment of the invention is not limited thereto, and the dry etching of the (2-1)-th dummy layer D21-I may be performed as a separate process from the dry etching process of the (1-1)-th dummy layer D11-I. A portion of the (3-1)-th dummy layer D31-I overlapping the second anode AE2 and the third anode AE3 may be patterned to be removed by dry-etching the (3-1)-th dummy layer D31-I together, and a (3-1)-th dummy pattern D31 having a closed-line shape surrounding the first light-emitting region PXA-R (see FIG. 4) on a plane may be formed.

After the second group process, a third group process may be performed. In an embodiment, a second light-emitting element ED2 (see FIG. 10H) and a second lower encapsulation inorganic pattern LIL2 (see FIG. 10H) covering the second light-emitting element ED2 (see FIG. 10H) may be formed through the third group process. Hereinafter, the third group process will be described with reference to FIGS. 10F to 10H.

Referring to FIG. 10F, the third group process according to an embodiment may include removing the second photoresist layer PR2 (see FIG. 10E) and forming a third photoresist layer PR3. A second photo opening OP2-R overlapping the second groove GR2 (see FIG. 9H) may be formed in the third photoresist layer PR3.

Hereafter, the third group process according to an embodiment may include forming a second partition wall opening OP2-P in the partition wall PW through the first and second etching processes, forming a second light-emitting opening OP2-E in the pixel defining layer PDL through the third etching process, and forming a second sacrificial opening OP2-S in the second sacrificial pattern SP2 through the fourth etching process.

In an embodiment, at least a portion of the second anode AE2 may be exposed by the second partition wall opening OP2-P, the second light-emitting opening OP2-E, and the second sacrificial opening OP2-S. The description of the first to fourth etching processes of the second group process described above with reference to FIGS. 10A to 10D may be similarly applied to the first to fourth etching processes of the third group process. The first to fourth etching processes of the third group process may be performed by using the third photoresist layer PR3 as a mask.

In an embodiment, referring to FIG. 10G, the third group process according to this embodiment may include removing the third photoresist layer PR3 (see FIG. 10F). Hereafter, the third group process according to an embodiment may include forming a second light-emitting pattern EP2, forming a second cathode CE2, forming a second capping pattern CP2, and forming a second lower encapsulation inorganic layer LIL2-I.

In an embodiment, first, the forming of the second light-emitting pattern EP2, the forming of the second cathode CE2, and the forming of the second capping pattern CP2 may be respectively performed in methods similar to those of the forming of the first light-emitting pattern EP1 (see FIG. 10D), the forming of the first cathode CE1 (see FIG. 10D), and the forming of the first capping pattern CP1 (see FIG. 10D) in the second group process. Meanwhile, the second light-emitting pattern EP2 may be formed by depositing a second organic material, and the second organic material may include the same material as the first organic material or may include a different material from the first organic material.

In an embodiment, in the forming of the second light-emitting pattern EP2, a (1-2)-th dummy layer D12-I spaced apart from the second light-emitting pattern EP2 may be formed together, and in the forming of the second cathode CE2, a (2-2)-th dummy layer D22-I spaced apart from the second cathode CE2 may be formed together, and in the forming of the second capping pattern CP2, a (3-2)-th dummy layer D32-I spaced apart from the second capping pattern CP2 may be formed together. A portion of each of the (1-2)-th dummy layer D12-I, the (2-2)-th dummy layer D22-I, and the (3-2)-th dummy layer D32-I may be disposed on the first light-emitting element ED1 in the first partition wall opening OP1-P, and another portion of each of the (1-2)-th dummy layer D12-I, the (2-2)-th dummy layer D22-I, and the (3-2)-th dummy layer D32-I may be disposed on the partition wall PW so as to entirely overlap the upper surface of the partition wall PW.

In an embodiment, the forming of the second lower encapsulation inorganic layer LIL2-I may be performed in a method similar to that of the forming of the first lower encapsulation inorganic layer LIL1-I (see FIG. 10D) in the first group process. A portion of the second lower encapsulation inorganic layer LIL2-I may cover the second light emitting element ED2 in the second partition wall opening OP2-P. Another portion of the second lower encapsulation inorganic layer LIL2-I may be disposed on the first light-emitting element ED1, and still another portion of the second lower encapsulation inorganic layer LIL2-I may be formed on the partition wall PW so as to entirely overlap the upper surface of the partition wall PW.

Referring to FIGS. 10G and 10H, the third group process according to an embodiment may include forming a fourth photoresist layer PR4, patterning the second lower encapsulation inorganic layer LIL2-I through the fifth etching process, and patterning the (1-2)-th dummy layers D12-I through the sixth etching process.

In an embodiment, the fourth photoresist layer PR4 may be formed on the second lower encapsulation inorganic layer LIL2-I and may be formed in a pattern shape disposed to correspond to the second light-emitting opening OP2-E.

In an embodiment, the patterning of the second lower encapsulation inorganic layer LIL2-I and the patterning of the (1-2)-th dummy layer D12-I may be respectively performed in methods similar to those of the patterning of the first lower encapsulation inorganic layer LIL1-I (see FIG. 10D) and the patterning of the (1-1)-th dummy layer D11-I (see FIG. 10D) in the second group process. In the fifth etching process and the sixth etching process of the third group process, the fourth photoresist layer PR4 may be used as a mask.

In an embodiment, in the third group process, the second lower encapsulation inorganic pattern LIL2 may be formed from the second lower encapsulation inorganic layer LIL2-I through the fifth etching process. The second lower encapsulation inorganic pattern LIL2 may be disposed to correspond to the second light-emitting opening OP2-E. A portion of the second lower encapsulation inorganic pattern LIL2 may be disposed in the second partition wall opening OP2-P and cover the second light-emitting element ED2, and another portion of the second lower encapsulation inorganic pattern LIL2 may be disposed on the partition wall PW.

In an embodiment, through the sixth etching process, the (1-2)-th dummy pattern D12 may be formed from the (1-2)-th dummy layer D12-I. The (1-2)-th dummy pattern D12 may have a closed-line shape surrounding the second light-emitting region PXA-G (see FIG. 4) on a plane.

In an embodiment, in the sixth etching process, by dry-etching the (2-2)-th dummy layer D22-I and the (3-2)-th dummy layer D32-I together, the (2-2)-th dummy pattern D22 and the (3-2)-th dummy pattern D32 having a closed-line shape surrounding the second light-emitting region PXA-G (see FIG. 4) on a plane may be formed together.

After the third group process, a fourth group process may be performed. In an embodiment, a third light-emitting element ED3 (see FIG. 10K) and a third lower encapsulation inorganic pattern LIL3 (see FIG. 10K) covering the third light-emitting element ED3 (see FIG. 10K) may be formed through the fourth group process. Hereinafter, the fourth group process will be described with reference to FIGS. 10I to 10K.

Referring to FIG. 10I, the fourth group process according to an embodiment may include removing the fourth photoresist layer PR4 (see FIG. 10H) and forming a fifth photoresist layer PR5. A third photo opening OP3-R overlapping the third groove GR3 (see FIG. 9I) may be formed in the fifth photoresist layer PR5.

Hereafter, the fourth group process according to an embodiment may include forming a third partition wall opening OP3-P in the partition wall PW through the first and second etching processes, forming a third light-emitting opening OP3-E in the pixel defining layer PDL through the third etching process, and forming a third sacrificial opening OP3-S in the third sacrificial pattern SP3 through the fourth etching process.

In an embodiment, at least a portion of the third anode AE3 may be exposed by the third partition wall opening OP3-P, the third light-emitting opening OP3-E, and the third sacrificial opening OP3-S. The descriptions of the first to fourth etching processes of the second group process described above with reference to FIGS. 10A to 10D may be similarly applied to the first to fourth etching processes of the fourth group process. The first to fourth etching processes of the fourth group process may be performed by using the fifth photoresist layer PR5 as a mask.

Referring to FIG. 10J, the fourth group process according to an embodiment may include removing the fifth photoresist layer PR5 (see FIG. 10I). Hereafter, the fourth group process according to an embodiment may include forming a third light-emitting pattern EP3, forming a third cathode CE3, forming a third capping pattern CP3, and forming a third lower encapsulation inorganic layer LIL3-I.

In an embodiment, first, the forming of the third light-emitting pattern EP3, the forming of the third cathode CE3, and the forming of the third capping pattern CP3 may be respectively performed in methods similar to those of the forming of the first light-emitting pattern EP1 (see FIG. 10D), the forming of the first cathode CE1 (see FIG. 10D), and the forming of the first capping pattern CP1 (see FIG. 10D) in the second group process. Meanwhile, the third light-emitting pattern EP3 may be formed by depositing a third organic material, and the third organic material may include a material different from the first organic material and the second organic material or may include the same material as the first organic material or the second organic material.

In an embodiment, in the forming of the third light-emitting pattern EP3, a (1-3)-th dummy layer D13-I spaced apart from the third light-emitting pattern EP3 may be formed together, and in the forming of the third cathode CE3, a (2-3)-th dummy layer D23-I spaced apart from the third cathode CE3 may be formed together, and in the forming of the third capping pattern CP3, a (3-3)-th dummy layer D33-I spaced apart from the third capping pattern CP3 may be formed together. A portion of each of the (1-3)-th dummy layer D13-I, the (2-3)-th dummy layer D23-I, and the (3-3)-th dummy layer D33-I may be disposed on the first light-emitting element ED1 in the first partition wall opening OP1-P, another portion of each of the (1-3)-th dummy layer D13-I, the (2-3)-th dummy layer D23-I, and the (3-3)-th dummy layer D33-I may be disposed on the second light-emitting element ED2 in the second partition wall opening OP2-P, and still another portion of each of the (1-3)-th dummy layer D13-I, the (2-3)-th dummy layer D23-I, and the (3-3)-th dummy layer D33-I may be disposed on the partition wall PW so as to entirely overlap the upper surface of the partition wall PW.

In an embodiment, the forming of the third lower encapsulation inorganic layer LIL3-I may be formed in a method similar to that of the forming of the first lower encapsulation inorganic layer LIL1-I (see FIG. 10D) in the first group process. A portion of the third lower encapsulation inorganic layer LIL3-I may cover the third light emitting element ED3 in the third partition wall opening OP3-P. Another portion of the third lower encapsulation inorganic layer LIL3-I may be disposed on the first light-emitting element ED1, still another portion of the third lower encapsulation inorganic layer LIL3-I may be disposed on the second light-emitting element ED2, and still another portion of the third lower encapsulation inorganic layer LIL3-I may be formed on the partition wall PW so as to entirely overlap the upper surface of the partition wall PW.

Referring to FIGS. 10J and 10K, the fourth group process according to an embodiment may include forming a sixth photoresist layer PR6, patterning the third lower encapsulation inorganic layer LIL3-I through the fifth etching process, and patterning a (1-3)-th dummy layer D13-I through the sixth etching process.

In an embodiment, the sixth photoresist layer PR6 may be formed on the third lower encapsulation inorganic layer LIL3-I and may be formed in a pattern shape corresponding to the third light-emitting opening OP3-E.

In an embodiment, the patterning of the third lower encapsulation inorganic layer LIL3-I and the patterning of the (1-3)-th dummy layer D13-I may be respectively performed in methods similar to those of the patterning of the first lower encapsulation inorganic layer LIL1-I (see FIG. 10D) and the patterning of the (1-1)-th dummy layer D11-I (see FIG. 10D) in the second group process. In the fifth etching process and the sixth etching process of the fourth group process, the sixth photoresist layer PR6 may be used as a mask.

In an embodiment, in the fourth group process, a third lower encapsulation inorganic pattern LIL3 may be formed from the third lower encapsulation inorganic layer LIL3-I through the fifth etching process. The third lower encapsulation inorganic pattern LIL3 may be disposed to correspond to the third light-emitting opening OP3-E. A portion of the third lower encapsulation inorganic pattern LIL3 may be disposed in the third partition wall opening OP3-P and cover the third light-emitting element ED3, and another portion of the third lower encapsulation inorganic pattern LIL3 may be disposed on the partition wall PW.

In an embodiment, through the sixth etching process, a (1-3)-th dummy pattern D13 may be formed from the (1-3)-th dummy layer D13-I. The (1-3)-th dummy pattern D13 may have a closed-line shape surrounding the third light-emitting region PXA-B (see FIG. 4) on a plane.

In an embodiment, in the sixth etching process, by dry-etching the (2-3)-th dummy layer D23-I and the (3-3)-th dummy layer D33-I together, a (2-3)-th dummy pattern D23 and a (3-3)-th dummy pattern D33 having a closed-line shape surrounding the third light-emitting region PXA-B (see FIG. 4) on a plane may be formed together.

In an embodiment, hereafter, the fifth group process may be performed, and the display panel DP (see FIG. 10L) including an encapsulation layer TFE (see FIG. 10L) may be completed through the fifth group process.

Referring to FIG. 10L, the fifth group process according to an embodiment may include forming an encapsulation organic layer OL on the first lower encapsulation inorganic pattern LIL1, the second lower encapsulation inorganic pattern LIL2, and the third lower encapsulation inorganic pattern LIL3 and the partition wall PW and forming an upper encapsulation inorganic layer UIL on the encapsulation organic layer OL. Through this, the display panel DP including the base layer BL, the circuit element layer D-CL, the insulating layer 50, the display element layer D-OL, and the encapsulation layer TFE may be formed.

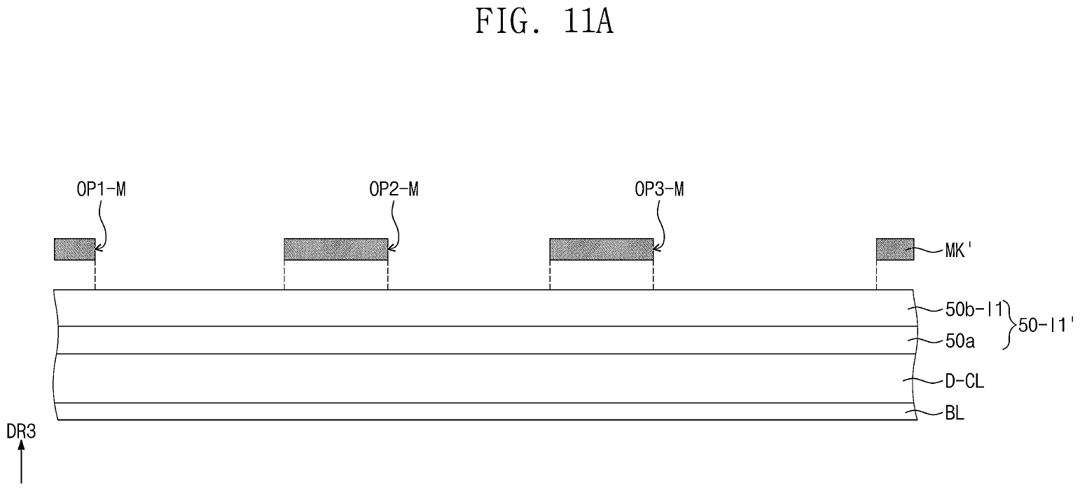

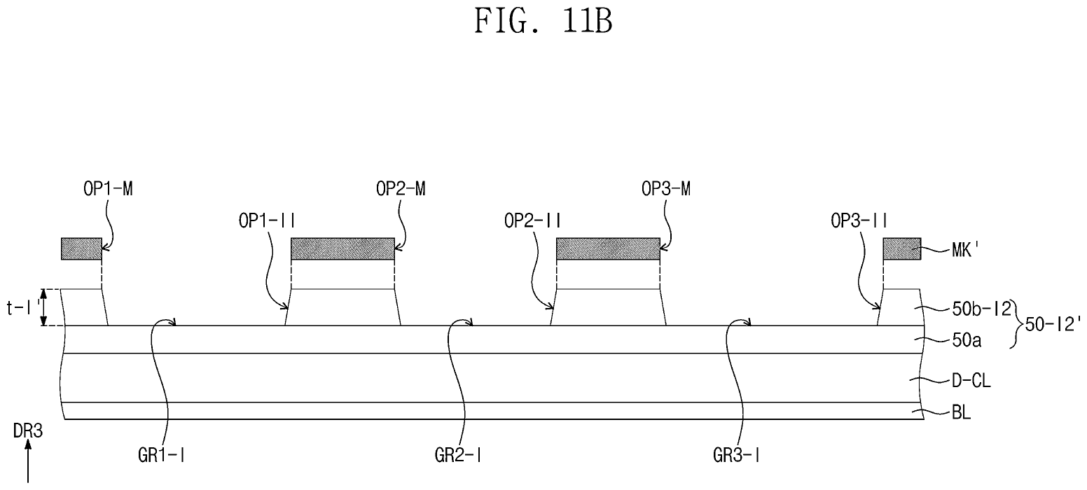

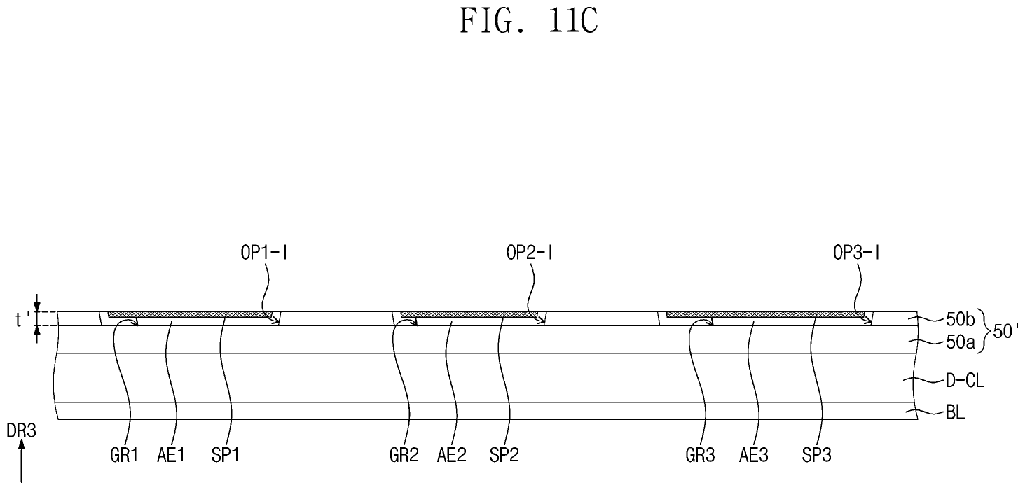

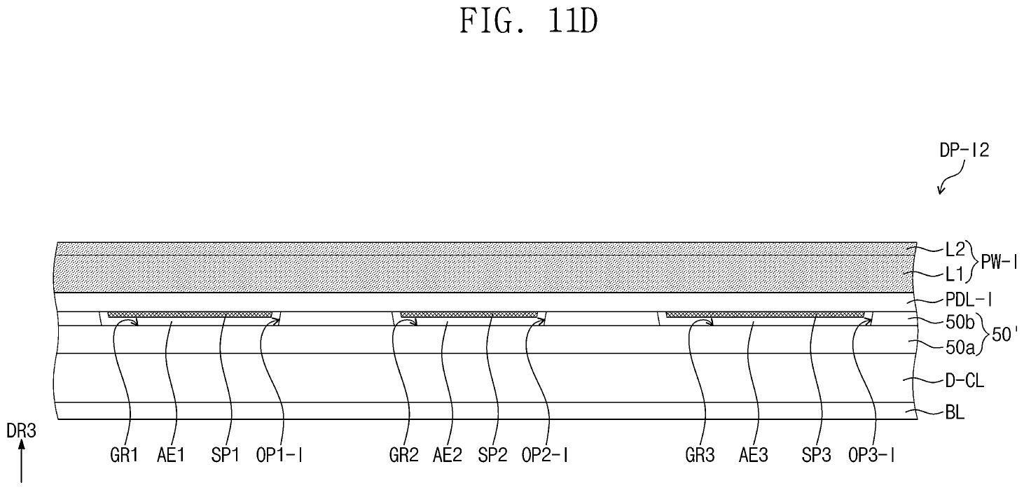

FIGS. 11A to 11C are cross-sectional views illustrating some steps of the method of manufacturing the display panel according to an embodiment of the invention. The method of manufacturing the display panel according to an embodiment may be partially different from the first group process described above with reference to FIGS. 9A to 9I. Same/similar reference numerals will be used for the same/similar elements as those described in FIGS. 9A to 9I, redundant descriptions will be omitted, and differences will be mainly explained.

First, referring to FIG. 11A, the first group process according to an embodiment may include forming a first preliminary insulating layer 50-I1′ on the base substrate. In an embodiment, the first preliminary insulating layer 50-I1′ may include a lower film 50a deposited and formed on an insulating layer (e.g., the fourth insulating layer 40 of FIG. 5A) disposed at the uppermost side of the circuit element layer D-CL and a first preliminary upper film 50b-I1 deposited and formed on the lower film 50a.

Hereafter, referring to FIGS. 11A and 11B, the first group process according to an embodiment may include patterning the preliminary insulating layer 50-I1′ so that a second preliminary insulating layer 50-I2′ is formed from the first preliminary insulating layer 50-I1′. In an embodiment, the second preliminary insulating layer 50-I2′ including the lower film 50a and a second preliminary upper film 50b-I2 may be formed through an exposure process and a developing process of the first preliminary upper film 50b-I1 of the first preliminary insulating layer 50-I1′.

In an embodiment, a first mask opening OP1-M, a second mask opening OP2-M, and a third mask opening OP3-M may be defined in a mask MK′ used in the exposure process of the first preliminary upper film 50b-I1, and light passing through the mask openings OP1-M, OP2-M, and OP3-M among provided light may be provided to a portion of the first preliminary upper film 50b-I1 overlapping the mask openings OP1-M, OP2-M, and OP3-M. In an embodiment, the mask MK′ may block the provided light, and light may not be provided to a portion of the first preliminary upper film 50b-I1 overlapping the mask MK′.

In an embodiment, hereafter, as the portion of the first preliminary upper film 50b-I1 overlapping the first mask opening OP1-M, the second mask opening OP2-M, and the third mask opening OP3-M is removed through the developing process of the first preliminary upper film 50b-I1 exposed to light, the second preliminary upper film 50b-I2 having a first initial opening OP1-II, a second initial opening OP2-II, and a third initial opening OP3-II defined therein and respectively corresponding to the first mask opening OP1-M, the second mask opening OP2-M, and the third mask opening OP3-M may be formed.

In an embodiment, the first initial opening OP1-II of the second preliminary upper film 50b-I2 and the upper surface of the lower film 50a exposed by the first initial opening OP1-II may form the first initial groove GR1-I of the second preliminary insulating layer 50-I2′, the second initial opening OP2-II of the second preliminary upper film 50b-I2 and the upper surface of the lower film 50a exposed by the second initial opening OP2-II may form the second initial groove GR2-I of the second preliminary insulating layer 50-I2′, and the third initial opening OP3-II of the second preliminary upper film 50b-I2 and the upper surface of the lower film 50a exposed by the third initial opening OP3-II may form the third initial groove GR3-I of the second preliminary insulating layer 50-I2′.

In an embodiment, hereafter, in a method similar to what is described with reference to FIGS. 9D to 9F, by performing the forming of a conductive layer CL (see FIG. 9D) on the second preliminary insulating layer 50-I2′, the forming of a sacrificial layer SL (see FIG. 9D) on the conductive layer CL (see FIG. 9D), and the patterning of each of the conductive layer CL (see FIG. 9D) and the sacrificial layer SL (see FIG. 9D), the first preliminary display panel DP-I1 (see FIG. 9F) may be formed which includes a base layer BL, a circuit element layer D-CL, a second preliminary insulating layer 50-I2′, first to third preliminary anodes AE1-I, AE2-I, and AE3-I (see FIG. 9E), and first to third preliminary sacrificial patterns SP1-I, SP2-I, and SP3-I (see FIG. 9E).

Referring to FIGS. 11B and 11C, the first group process according to an embodiment may form an insulating layer 50′ from the second preliminary insulating layer 50-I2′ through the planarization of the first preliminary display panel DP-I1 (see FIG. 9F). The insulating layer 50′ of FIG. 11C may correspond to the fifth insulating layer 50′ described above with reference to FIG. 7. The description given above with reference to FIG. 9G may be similarly applied to the planarization process of the first preliminary display panel DP-I1 (see FIG. 9F).

In an embodiment, by removing a portion of the second preliminary upper film 50b-I2 of the second preliminary insulating layer 50-I2′, the upper film 50b, in which the first to third openings OP1-I, OP2-I, and OP3-I are defined, may be formed from the second preliminary upper film 50b-I2. A thickness t′ of the upper film 50b may be smaller than a thickness t-I′ of the second preliminary upper film 50b-I2.

In an embodiment, the first opening OP1-I of the upper film 50b and the upper surface of the lower film 50a exposed from the first opening OP1-I may form a first groove GR1, the second opening OP2-I of the upper film 50b and the upper surface of the lower film 50a exposed from the second opening OP2-I may form a second groove GR2, and the third opening OP3-I of the upper film 50b and the upper surface of the lower film 50a exposed from the third opening OP3-I may form a third groove GR3.

In an embodiment, through the planarization process, the thickness (or the depth of the first groove GR1, the second groove GR2, and the third groove GR3) of the upper film 50b may be provided to be substantially equal to the sum of the thickness of the first portions P1 (see FIG. 9H) of the first anode AE1, the second anode AE2, and the third anode AE3 and the thickness of the first sacrificial pattern SP1, the second sacrificial pattern SP2, and the third sacrificial pattern SP3. Accordingly, the upper surface of each of the first anode AE1, the second anode AE2, and the third anode AE3, the upper surface of each of the first sacrificial pattern SP1, the second sacrificial pattern SP2, and the third sacrificial pattern SP3, and the upper surface of the insulating layer 50′ may be substantially coplanar with each other. That is, the anodes AE1, AE2, and AE3, the sacrificial patterns SP1, SP2, and SP3, and the insulating layer 50′ may provide a flat surface.

Referring to FIG. 11D, the first group process according to an embodiment may include forming a preliminary pixel defining layer PDL-I on the insulating layer 50′ and forming a preliminary partition wall PW-I on the preliminary pixel defining layer PDL-I.

In an embodiment, the preliminary pixel defining layer PDL-I may be disposed on the upper film 50b of the insulating layer 50′. As the preliminary pixel defining layer PDL-I is disposed on a flat surface provided by the anodes AE1, AE2, and AE3, the sacrificial patterns SP1, SP2, and SP3, and the upper film 50b, the preliminary pixel defining layer PDL-I may also be provided to be flat.

In an embodiment, the preliminary partition wall PW-I may include a first layer L1 disposed on the preliminary pixel defining layer PDL-I and a second layer L2 disposed on the first layer L1. As the preliminary partition wall PW-I is disposed on the preliminary pixel defining layer PDL-I provided to be flat, both the first layer L1 and the second layer L2 may be provided to be flat.

In an embodiment, through the first group process, a second preliminary display panel DP-I2 may be formed which includes a base layer BL, a circuit element layer D-CL, an insulating layer 50′, a first anode AE1, a second anode AE2, and a third anode AE3, a first sacrificial pattern SP1, a second sacrificial pattern SP2, and a third sacrificial pattern SP3, a preliminary pixel defining layer PDL-I, and a preliminary partition wall PW-I. Hereafter, as the second to fifth group processes described above in FIGS. 10A to 10L are sequentially performed, the display panel DP′ (see FIG. 7) may be completed. The descriptions given above in FIGS. 10A to 10L may be equally applied to the second to fifth group processes according to an embodiment.

In an embodiment, as a light-emitting pattern patterned without a metal mask may be provided, it is possible to provide a display panel capable of improving process reliability and easily implementing high resolution.

According to an embodiment, by providing a flat base surface on which a pixel defining layer and a partition wall are disposed, a step difference may not be formed on the pixel defining layer and the partition wall. Through this, the lifting phenomenon of a tip portion in the partition wall may be prevented, thereby making it possible to prevent the formation of a defective light-emitting element in which electrical connection with the partition wall is blocked. Accordingly, a display panel with improved process reliability may be provided.

In addition, according to an embodiment, as a flat pixel defining layer and a flat partition wall are provided, it is possible to reduce the area of a margin region required for an anode in order to prevent the lifting phenomenon of the tip portion. Accordingly, a display panel with improved display efficiency and improved degree of design freedom may be provided.

According to an embodiment, it is possible to provide a method of manufacturing a display panel capable of easily implementing high resolution and improving process reliability, the degree of design freedom, and display efficiency.

While this invention has been described with reference to embodiments thereof, it will be clear to those of ordinary skill in the art to which the invention pertains that various changes and modifications may be made to the described embodiments without departing from the spirit and technical area of the invention as defined in the appended claims and their equivalents. Thus, the scope of the invention shall not be restricted or limited by the foregoing description, but be determined by the broadest permissible interpretation of the following claims. Moreover, the embodiments or parts of the embodiments may be combined in whole or in part without departing from the scope of the invention.

What is claimed is:

1. A display panel comprising:
a base layer;
an insulating layer having a groove defined thereon, wherein the insulating layer is disposed on the base layer;
an anode disposed in the groove;
a pixel defining layer disposed on the insulating layer and having a light-emitting opening defined therein and exposing at least a portion of the anode;
a partition wall, having a partition wall opening defined therein and corresponding to the light-emitting opening, comprising a tip portion, and disposed on the pixel defining layer;
a cathode at least partially disposed in the partition wall opening and in contact with an inner side surface of the partition wall defining the partition wall opening; and
a light-emitting pattern disposed between the anode and the cathode,
wherein the anode comprises:
a first portion; and
a second portion protruding from the first portion toward the pixel defining layer and covered by the pixel defining layer.

2. The display panel of claim 1, wherein an upper surface of the second portion covered by the pixel defining layer is substantially coplanar with an upper surface of the insulating layer.

3. The display panel of claim 1, further comprising a sacrificial pattern disposed on the first portion, covered by the pixel defining layer, and having a sacrificial opening defined therein and corresponding to the light-emitting opening,
wherein the sacrificial pattern is surrounded by the second portion.

4. The display panel of claim 3, wherein an upper surface of the sacrificial pattern and an upper surface of the insulating layer are substantially coplanar with each other.

5. The display panel of claim 1, wherein the insulating layer is composed of a single film.

6. The display panel of claim 1, wherein:
the insulating layer comprises a lower film and an upper film, wherein the upper film includes an opening defined therein and is disposed on the lower film; and
wherein the groove is defined by the opening and an upper surface of the lower film exposed by the opening.

7. The display panel of claim 1, wherein the pixel defining layer is generally flat.

8. The display panel of claim 1, wherein the partition wall comprises:
a first layer comprising a first inner side surface defining a first region of the partition wall opening; and
a second layer disposed on the first layer and comprising a second inner side surface defining a second region of the partition wall opening,
wherein:
the first inner side surface is disposed more inward than the second inner side surface;
the tip portion corresponds to the second layer protruding from the first layer; and
an upper surface of the second layer is generally flat.

9. The display panel of claim 1, wherein the pixel defining layer comprises an inorganic insulating material.

10. The display panel of claim 1, further comprising:
a first dummy pattern disposed on the partition wall, comprising the same material as the light-emitting pattern, and spaced apart from the light-emitting pattern;
a second dummy pattern disposed on the first dummy pattern, comprising the same material as the cathode, and spaced apart from the cathode; and
a lower encapsulation inorganic pattern disposed to correspond to the light-emitting opening and disposed on the cathode and the second dummy pattern.

11. A method for manufacturing a display panel, the method comprising:
forming an anode in a groove defined in an insulating layer;
forming a partition wall disposed on the insulating layer and having a partition wall opening defined therein and overlapping the anode;
forming a pixel defining layer disposed between the insulating layer and the partition wall and having a light-emitting opening defined therein and corresponding to the partition wall opening;
forming a light-emitting pattern at least partially disposed in the groove and the light-emitting opening; and
forming a cathode at least partially disposed in the partition wall opening wherein the cathode is in contact with an inner side surface of the partition wall defining the partition wall opening, and
wherein an upper surface of the anode covered by the pixel defining layer is substantially coplanar with an upper surface of the insulating layer.

12. The method of claim 11, further comprising, before the forming of the anode:
depositing a first preliminary insulating layer on a base layer; and
forming an initial groove in the first preliminary insulating layer so that a second preliminary insulating layer is formed from the first preliminary insulating layer,
wherein the forming of the initial groove in the first preliminary insulating layer comprises:
providing light to the first preliminary insulating layer by using a mask having a mask opening defined therein; and
removing a portion of the first preliminary insulating layer exposed to the light.

13. The method of claim 12, wherein in the providing of the light to the first preliminary insulating layer:
the light having a first amount of light per unit area is provided to a portion of the first preliminary insulating layer overlapping the mask opening; and
the light having a second amount of light per unit area is provided to a portion of the first preliminary insulating layer overlapping the mask,
wherein the first amount of light is greater than the second amount of light.

14. The method of claim 12, wherein the forming of the anode comprises:
forming a conductive layer on the second preliminary insulating layer;
patterning the conductive layer to form a preliminary anode, which overlaps the initial groove; and
removing a portion of the preliminary anode and a portion of the second preliminary insulating layer to form the anode and the insulating layer,
wherein, the groove is formed by removing the portion of the preliminary anode and the portion of the second preliminary insulating layer to have a smaller depth than the initial groove.

15. The method of claim 14, wherein:
the forming of the anode further comprises, after the forming of the conductive layer and before the patterning of the conductive layer, forming a sacrificial layer on the conductive layer and patterning the sacrificial layer so that a preliminary sacrificial pattern overlapping the initial groove is formed from the sacrificial layer; and
in the removing of the portion of the preliminary anode and the portion of the second preliminary insulating layer, a portion of the preliminary sacrificial pattern is removed so that a sacrificial pattern is formed from the preliminary sacrificial pattern,
wherein an upper surface of the sacrificial pattern is substantially coplanar with the upper surface of the insulating layer.

16. The method of claim 15, wherein:
the anode comprises a first portion and a second portion extending in a direction away from the base layer from the first portion and surrounding the sacrificial pattern; and
the upper surface of the anode is disposed in the second portion to be substantially coplanar with the upper surface of the insulating layer.

17. The method of claim 14, wherein the patterning of the conductive layer is performed by a wet etching method.

18. The method of claim 14, wherein the removing of the portion of the preliminary anode and the portion of the second preliminary insulating layer is performed by a chemical mechanical polishing (CMP) method.

19. The method of claim 14, wherein:
the depositing of the first preliminary insulating layer comprises depositing a lower film on the base layer and depositing a first preliminary upper film on the lower film;
wherein in the forming of the initial groove on the first preliminary insulating layer, a second preliminary upper film having an initial opening defined therein is formed from the first preliminary upper film, wherein the initial groove is formed by the initial opening and an upper surface of the lower film exposed from the initial opening; and
wherein in the removing of the portion of the preliminary anode and the portion of the second preliminary insulating layer, a portion of the second preliminary upper film is removed to form an upper film thinner than the second preliminary upper film, wherein an opening formed from the initial opening is defined in the upper film, and the groove is formed by the opening and the upper surface of the lower film exposed from the opening.

20. The method of claim 19, wherein in the providing of the light to the first preliminary insulating layer, the light is provided to a portion of the first preliminary insulating layer which overlaps the mask opening.
